(19) United States
(12) Patent Application Publication
(10) Pub. No.: US 2026/0204898 A1
(43) Pub. Date: Jul. 16, 2026

(54) DEVICE AND METHOD FOR ESTIMATING ELECTRICAL PROPERTIES, THERMAL PROPERTIES AND EXPECTED LIFE OF A CIRCUIT PROTECTION ELEMENT BASED ON TEMPERATURE MEASUREMENTS, AND FOR ESTIMATING ELECTRICAL CHARACTERISTICS OF A SYSTEM BASED ON TEMPERATURE MEASUREMENTS

(71) Applicant: MERSEN USA EP Corp., Boonton, NJ (US)

(72) Inventors: Ting PAN, Andover, MA (US); Roy BALL, Coral Springs, FL (US)

(73) Assignee: MERSEN USA EP Corp., Boonton, NJ (US)

(21) Appl. No.: 19/435,887

(22) Filed: Dec. 30, 2025

Related U.S. Application Data
(60) Provisional application No. 63/739,729, filed on Dec. 30, 2024.

(51) Int. Cl. H02H 9/04; H01C 7/12; H02H 5/04

(52) U.S. Cl. CPC H02H 9/042; H01C 7/12; H02H 5/04

(57) ABSTRACT

A device and method for detecting an electrical parameter of a circuit protection element includes measuring a temperature of the circuit protection element and, based on the measured temperature, determining a temperature rise of the circuit protection element. The electrical parameter of the circuit protection element is determined based on the temperature rise.

### RELATED APPLICATION DATA

This application claims priority of U.S. Provisional Application No. 63/739,729 filed on Dec. 30, 2024, which is incorporated herein by reference in its entirety.

### FIELD OF THE INVENTION

The present invention relates generally to circuit protection and, more particularly, to a device and method for estimating electrical properties, thermal properties and expected life of a circuit protection element, and for estimating electrical characteristics of a system in which the circuit protection element is installed, the estimation based on temperature measurements.

### BACKGROUND OF THE INVENTION

Many of today's highly sensitive electronic components, such as computer and computer-related equipment that are used in commercial and residential applications contain circuit protection devices. These devices protect sensitive and/or expensive electronic circuits and components from damage from various fault conditions, such as voltage surges/spikes.

A commonly used device to protect against voltage surges/spikes is a voltage-clamping element, such as a metal-oxide varistor (MOV) or the like, which is connected in parallel between a service power line and a ground or neutral line, or between a neutral line and a ground line. MOVs are non-linear, electronic devices made of ceramic-like materials comprising zinc-oxide grains and a complex amorphous inner granular material. Over a wide range of current, the voltage remains within a narrow band commonly called the varistor voltage. A log-log plot of the instantaneous voltage in volts versus the instantaneous current in amps yields a nearly horizontal line. It is this unique current-voltage characteristic that makes MOVs ideal devices for protection of sensitive electronic circuits against electrical surges, over-voltages, faults or shorts. When exposed to voltages exceeding their voltage value, MOVs become highly conductive devices that absorb and dissipate the energy related to the overvoltage and simultaneously limit dump current to a neutral line or ground plane.

Voltage-clamping elements, such as MOVs, have a finite lifespan and, to maintain circuit protection, such voltage-clamping elements need to be replaced prior to reaching their end of life. One cannot accurately estimate the remaining life of a voltage-clamping element by simple visual inspection. However, the remaining life of a voltage-clamping element can be estimated using multiple costly sensors and corresponding circuitry to measure voltage and current (at very different levels) and, based on the voltage and current measurements over the life of the voltage-clamping element, the remaining life is estimated.

### SUMMARY OF THE INVENTION

The present invention is directed to an apparatus and method for estimating electrical and/or thermal parameters of a circuit protection element, such as a voltage-clamping element (e.g., a MOV) or a fuse, and providing a life estimation of the circuit protection element using a single thermal sensor. Advantageously, the apparatus and method in accordance with the invention provide an economical approach to estimating a remaining life of a voltage-clamping element, without the need for costly sensors and corresponding circuitry.

According to one aspect of the invention, a surge protection device (SPD) couplable to a circuit includes: a voltage-clamping element configured to limit a voltage; and a processing device configured to receive temperature data corresponding to the voltage-clamping element, the processing device configured to determine, based on the temperature data, a temperature rise of the voltage-clamping element, and based on the temperature rise determine at least one of an electrical parameter of the voltage-clamping element, an electrical parameter of a circuit coupled to the SPD, an amount of life of the voltage-clamping element consumed by the electrical event, or a remaining life of the voltage-clamping element after subjected to the electrical event.

The SPD may include a first temperature sensor configured to measure a temperature of the voltage-clamping element, the first temperature sensor communicatively coupled to the processing device to provide the temperature data to the processing device.

In one embodiment, the determination of the electrical parameter is based solely on the temperature rise of the voltage-clamping element.

The SPD may include a second temperature sensor communicatively coupled to the processing device and configured to measure a temperature of ambient air about the voltage-clamping element, wherein the processing device is further configured to base said determination on the ambient air temperature about the voltage-clamping element.

In one embodiment the processing device includes a communication module configured to communicate with other equipment.

The SPD may include a first terminal and a second terminal for connecting the surge protection device to a circuit to be protected, and a thermal protection element, wherein the voltage-clamping element and the thermal protection element are electrically connected in series between the first and second terminals, and the thermal protection element is configured to disconnect the voltage-clamping element from at least one of the first or second terminals upon detecting an overload condition.

In one embodiment, the processing device is configured to determine a surge or an over voltage applied to the voltage-clamping element as a function of the temperature rise.

In one embodiment, the processing device is configured to determine a current through the voltage-clamping element as a function of the temperature rise.

In one embodiment, the processing device is configured to determine a leakage current of the voltage-clamping element as a function of the temperature rise.

In one embodiment, the processing device is configured to determine an amount of energy absorbed by the voltage-clamping element as a function of the temperature rise.

The SPD may include a housing including an interior space, wherein the voltage-clamping element is disposed at least partially within the interior space, and a thermal terminal thermally connected to the voltage-clamping element, wherein the first temperature sensor is disposed external to the housing and thermally connected to the thermal terminal.

According to another aspect of the invention, a method for detecting an electrical parameter of a voltage-clamping element includes: measuring a temperature of the voltage-clamping element; based on the measured temperature, determining a temperature rise of the voltage-clamping element; and calculating the electrical parameter of the voltage-clamping element based on the temperature rise.

In one embodiment, calculating the electrical parameter is based solely on the temperature rise of the voltage-clamping element.

The method may include measuring an ambient temperature about the voltage-clamping element, and wherein calculating the electrical parameter is based on the temperature rise of the voltage-clamping element and the ambient air temperature.

In one embodiment the electrical parameter is one of a surge or over voltage applied to the voltage-clamping element, a current applied to the voltage-clamping element, a leakage current of the voltage-clamping element, or an energy absorbed by the voltage-clamping element.

According to another aspect of the invention, a surge protection device (SPD) includes a housing including an interior space, and a voltage-clamping element disposed at least partially within the interior space, the voltage clamping element comprising a first electrode and a second electrode for electrically connecting the voltage-clamping element to a circuit to be protected, and a thermal terminal thermally connected to the voltage-clamping element, the first and second electrodes extending out of the housing.

In one embodiment the thermal terminal is connected to one of the first electrode or the second electrode.

In one embodiment the thermal terminal and one of the first or second electrodes are conductively connected to each other.

In one embodiment the thermal terminal is connected to a surface of the voltage-clamping element.

In one embodiment the thermal terminal comprises a non-electrically conductive material.

The SPD may include a temperature sensor disposed external to the housing, the temperature sensor thermally coupled to the thermal terminal.

The SPD may include a status indicator configured to provide a status of the voltage-clamping element.

In one embodiment the temperature sensor and the surge protection device are electrically coupled to terminals accessible external to the housing, wherein at least one of: the terminals comprise a first terminal and a second terminal, and the temperature sensor and the status indicator are electrically connected to the first terminal and the second terminal in a parallel or series configuration; the terminals comprise a first terminal, a second terminal and a third terminal, and the temperature sensor and the status indicator are each electrically connected to the first terminal, the status indicator is further electrically connected to the second terminal, and the temperature sensor is further electrically connected to the third terminal; or the terminals comprise a first terminal, a second terminal, a third terminal and a fourth terminal, and the temperature sensor is electrically connected to the first terminal and the second terminal, and the status indicator is electrically connected to the third terminal and the fourth terminal.

According to another aspect of the invention, a method for estimating an amount of life of a voltage-clamping element consumed due to an electrical event subjected to the voltage-clamping element, the method including: obtaining a temperature rise of the voltage-clamping element due to the electrical event; based on the temperature rise of the voltage clamping element, determining a pulse energy absorbed by the voltage-clamping element due to the electrical event; and obtaining energy absorption characteristics of the voltage-clamping element; determining the amount of life of the voltage-clamping element consumed due to the electrical event based on the pulse energy absorbed by the voltage-clamping element and the energy absorption characteristics of the voltage-clamping element.

In one embodiment, obtaining the energy absorption characteristics of the voltage-clamping element includes converting electrical specifications of the voltage-clamping element to an energy absorption curve representing a maximum energy the voltage-clamping element can absorb.

In one embodiment, the energy absorption characteristics include a maximum energy absorption of the voltage-clamping element, the method including: determining a cumulative energy absorbed by the voltage-clamping element over a prescribed time period; and determining a remaining life of the voltage clamping element based a difference between the maximum energy absorption and the cumulative energy absorbed by the voltage-clamping element.

The method may include determining a type of the electrical event, wherein determining the amount of life consumed is based on a type of electrical event.

In one embodiment, the type of event is one of a surge event or an over voltage event.

To the accomplishment of the foregoing and related ends, the invention, then, comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

The invention may take physical form in certain parts and arrangement of parts, an embodiment of which is described in detail in the specification and illustrated in the accompanying drawings, wherein:

FIG. 1A is a side view of an exemplary surge protection device (SPD) that may be used in accordance with an embodiment of the invention.

FIG. 1B is a schematic view of the internal circuitry of the SPD of FIG. 1A.

FIG. 2 is a schematic diagram illustrating an exemplary SPD system in accordance with an embodiment of the invention.

FIG. 3 is a table illustrating exemplary parameters that may be determined based on temperature of the SPD in accordance with the invention.

FIGS. 4A-4D graphically illustrate the envelope of the temperature change curve of an exemplary voltage clamp device during various events (surges, overvoltage, etc.).

FIG. 5 is a graph illustrating various temperature measurements associated with a voltage-clamping device.

FIG. 6 is a flowchart illustrating exemplary steps according to one embodiment for using a measured temperature of a voltage-clamping device to detect electrical and/or thermal events experienced by the voltage-clamping device and determining if the voltage-clamping device should be replaced in accordance with the invention.

FIG. 7 is a flowchart illustrating exemplary steps according to another embodiment for using a measured temperature of a voltage-clamping device to detect electrical and/or thermal events experienced by the voltage-clamping device and determining if the voltage-clamping device should be replaced.

FIG. 8 is an exemplary UI curve for a voltage-clamping device.

FIG. 9 is a flowchart illustrating exemplary steps according to another embodiment for recognizing the type of event that the voltage-clamping element has undergone along with voltage measuring.

FIG. 10 is a flowchart illustrating exemplary steps according to another embodiment for recognizing the type of event that the voltage-clamping element has undergone, without using the ambient temperature T_{A} to detect such events.

FIG. 11 illustrates a de-rating curve for an exemplary voltage-clamping element.

FIG. 12A illustrates the de-rating curve of FIG. 11 converted into a pulse energy, pulse width and number of pulses chart.

FIG. 12B is a comparison graph of FIG. 12A and FIG. 11.

FIG. 13 illustrates a surge waveform for an exemplary voltage-clamping element.

FIG. 14A is a graph showing a portion of the graph of FIG. 12A from 20-1000 micro seconds.

FIG. 14B is a graph showing a portion of the graph of FIG. 12A from 1000-10000 micro seconds.

FIG. 15 illustrates a chart of voltage-clamping element temperatures during a surge test showing the relationship between peak surge current and peak temperature changes.

FIG. 16 illustrates another scatter chart for an exemplary voltage-clamping element showing different temperature rises (temperature variation curve) for a series of identical surges at different starting temperatures, which can be used to derive the temperature compensation value.

FIG. 17 illustrates shows an example of curve fitting for temperature compensation Tdiff (Equation 2).

FIGS. 18A and 18B are graphs illustrating an exemplary curve fitting for deriving the coefficients used in various equations.

FIGS. 19A-19C illustrate another exemplary surge protection device (SPD) that includes a thermal terminal in accordance with an embodiment of the invention.

FIGS. 20A-20D illustrate an exemplary cover for interfacing with the thermal terminal of FIGS. 19A-19D in accordance with an embodiment of the invention.

FIGS. 21A-21H illustrate exemplary embodiments of a surge protection device in accordance with the invention.

### DETAILED DESCRIPTION OF THE INVENTION

Embodiments of the present invention will now be described with reference to the drawings, wherein like reference numerals are used to refer to like elements throughout. It will be understood that the figures are not necessarily to scale.

Aspects of the invention will be chiefly described with respect to a circuit protection element in the form of a voltage-clamping element. It will be appreciated that aspects of the invention are applicable other types of circuit protection elements, such as fuses or the like.

In accordance with the present invention, a method and a surge protection device are provided, where one or more parameters of a voltage-clamping element of the surge protection device is/are determined based on a temperature rise of the voltage-clamping element, where the temperature rise is due to energy absorbed by the voltage-clamping element from to the electrical event. The parameters include a current and/or a voltage subjected to the voltage-clamping element and/or a current and/or a voltage of a circuit to which the surge protection device is connected, an amount of life of the voltage-clamping element that was consumed due to the electrical event, and a remaining life of the voltage-clamping element after the event. As will be discussed in further detail below, in accordance with one aspect of the invention the type of electrical event (e.g., a surge event or an overvoltage event) subjected to the voltage-clamping element is determined, for example, based on characteristics of the temperature rise of the voltage-clamping element. Based on the type of electrical event, the current and/or voltage subjected to the voltage-clamping element is/are calculated using the temperature rise of the voltage-clamping element. Further, based on the calculated current and/or voltage subjected to the voltage-clamping element due to the event, the energy absorbed by the voltage-clamping element may be calculated and compared to a bearable pulse number for the voltage-clamping element, the bearable pulse number obtained from manufacturer's specifications of the voltage-clamping element. Based on the comparison of the energy absorbed by the voltage-clamping element and the bearable number of pulses of the voltage-clamping element, an amount of life consumed by the electrical event and/or the remaining life of the voltage-clamping element may be calculated. The remaining life can be used to alert maintenance personnel that the voltage-clamping element is nearing the end of its life and should be replaced.

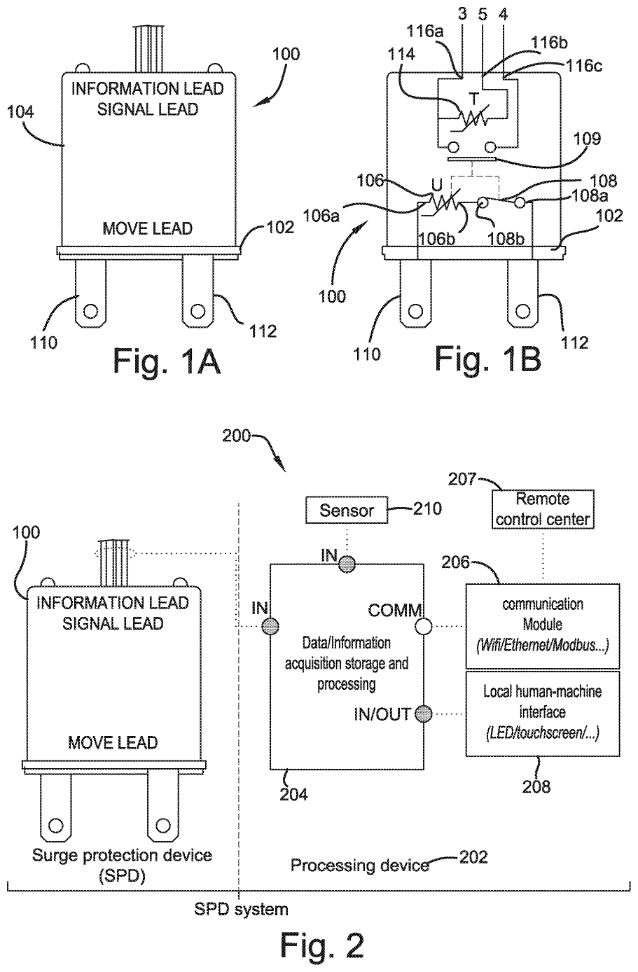

Referring to FIGS. 1A and 1B, illustrated is an exemplary surge protection device (SPD) 100 in accordance with an embodiment of the invention. The SPD 100 includes a base 102 to which components of the SPD are mounted, and a housing 104 that attaches to the base 102 to cover and protect the components. Attached to the base 102 is a voltage-clamping element 106, such as a varistor, e.g., a metal oxide varistor (MOV), a transient voltage suppressor (TVS) and the like, and a thermal protection element 108. A first terminal 106a of the voltage-clamping element 106 is electrically connected to a first terminal 110 of the SPD 100 and a first terminal 108a of the thermal protection element 108 is electrically connected to a second terminal 112 of the SPD 100. A second terminal 106b of the voltage-clamping element 106 and a second terminal 108b of the thermal protection element 108 are electrically connected to each other. In the event of an overload condition, the thermal protection element 108 will open (trip) and electrically disconnect the voltage-clamping element 106 from the second terminal 112, thereby removing the overload condition.

The thermal protection element 108 includes a status indicator 109, e.g., a micro switch that changes state as the thermal protection element 108 moves from the ready condition to the tripped condition. In the illustrated embodiment, the status indicator 109 is in the open state when the thermal protection element 108 is in the ready condition, and moves to the closed state when the thermal protection element 108 is in the tripped condition. It will be appreciated that the status indicator may be configured such that it is in the closed state when the thermal protection element 108 is in the ready condition, and in the open state when the thermal protection element 108 is in the tripped condition.

The SPD 100 further includes a temperature sensor 114, such as a thermocouple, a negative temperature coefficient thermistor (NTC), a resistive temperature device (RTD), and the like arranged within the housing 10. The temperature sensor 114 is configured to monitor a temperature of the voltage-clamping element 106 and preferably is attached directly to the voltage-clamping element 106. For example, the temperature sensor 114 may be bonded to the voltage-clamping element 106. Alternatively, a contactless sensor (e.g., an infrared temperature sensor or other contactless sensing means) may be disposed within the housing 104 or outside the housing 104 and arranged to monitor a temperature of the voltage-clamping element 106. In one embodiment, a first conductor of each of the temperature sensor 114 and the status indicator 109 is electrically connected to terminal 116a, a second conductor of the temperature sensor 114 is electrically connected to terminal 116b, and a second conductor of the status indicator 109 is electrically connected to terminal 116c. In this manner, both the temperature of the voltage-clamping element 106 and the status of the thermal protection element 108 can be remotely monitored using a three-wire connection 118. Alternatively, the status indicator 109 and the temperature sensor 114 may be connected in series or parallel, thereby allowing a two-wire connection to be utilized, if desired. When connected in series (normally closed indicator 109) or parallel (normally open indicator 109), temperature readings are possible when the thermal protection element 108 has not tripped, but are not possible when the thermal protection element 108 has tripped. In yet another variation, the status indicator 109 and the temperature sensor 114 are electrical connected to terminals such that they are isolated from each other, e.g., the status indicator 109 is electrical connected to first and second terminals, and the temperature sensor 114 is electrically connected to third and fourth terminals. In this manner, both the temperature and the status can be obtained while the respective signals are electrically isolated from one another.

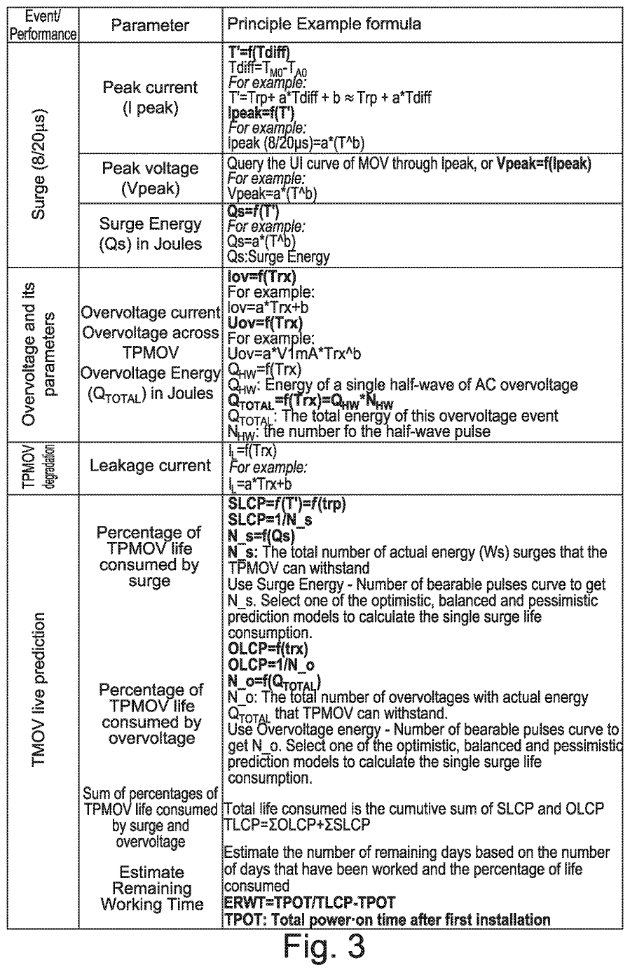

With additional reference to FIG. 2, the SPD 100 can be part of a SPD system 200 that includes the SPD 100 along with a processing device 202, where the SPD 100 is communicatively coupled to the processing device 202. As discussed in further detail below, the processing device 202 analyzes the data provided by the SPD 100, determines various parameters of the voltage-clamping element 106 (e.g., an amount of life remaining in the voltage-clamping element 106, surge current, leakage current, overvoltage, etc.) and communicates the results of the analysis along with status information to other devices. In particular, the processing device 202 analyzes the temperature of the voltage-clamping element 106 to determine parameters of the voltage-clamping element 106. In one embodiment, the processing device 202 determines the parameters based solely on the temperature of the voltage-clamping element 106, and in another embodiment the processing device 202 determines the parameters based on a difference in temperature of the voltage-clamping element 106 and the ambient temperature at the voltage-clamping element 106, which enhances the calculation accuracy. Coupled with the timing of the respective temperature changes, most events and voltage-clamping element performance can be determined. Briefly referring to FIG. 3, illustrated are exemplary parameters of the voltage-clamping element (surge current, overvoltage and associated current, and degradation) that may be calculated based on temperature, along with the formula to perform the calculation and the range. These formulas are discussed in further detail below. In all the formulas in FIG. 3 the temperature difference between device and ambient could be used to provide a much more accurate reading. Also, all of the applicable measurements, unless noted otherwise, are applicable to AC, DC and Pulse measurements (pulse being specified). Finally, the coefficients in each formula may use the same letters, but they may be different for different formulas.

The processing device 202 includes a data and communication platform 204 that is communicatively coupled to the SPD 100 to receive information therefrom. The data and communication platform 202 includes logic configured to receive data such as a temperature of the voltage-clamping element 106 and a status of the thermal protection element 108 (via status indicator 109). The logic of the communication platform 204 may be embodied as dedicated hardware circuits and/or programmable logic. Communicatively coupled to the data and communications platform 204 is a communication module 206 that includes one or both of wireless communications and/or wired (e.g., Ethernet) communications. The communication module 206 enables the processing device 202 to communicate information concerning the SPD 100, such as remaining life, temperature, status of the thermal protection element, etc., to other remote devices, such as a remote control center 207. An optional human-machine interface (HMI) 208 is also communicatively coupled to the data communications platform 204 and enables users access to the system. The processing device 202 may optionally include an ambient temperature sensor 210 for monitoring a temperature of the ambient environment at the SPD 100. Alternatively, the ambient temperature sensor 210 may be mounted on the SPD 100 and communicatively coupled to the processing device 202. As discussed in further detail below, temperature measurements obtained from such ambient temperature sensor 210 can be used in combination with the temperature of the voltage-clamping element 106 as obtained by temperature sensor 114 to improve the accuracy of the end of life estimation.

In operation, and as will be explained in further detail below, the temperature sensor 114 measures a temperature of the voltage-clamping element 106 (referred to herein as T_{M}) and provides the measured temperature to the processing device 202. Optionally, the ambient temperature sensor 210 measures a temperature of the ambient environment, i.e., the environment in which the SPD 100 resides, and provides the measured ambient temperature (referred to herein as T_{A}) to the processing device 202. The processing device 202 records and compares changes in T_{M} as well as time period over which the changes occur, and determines the type of electrical event (e.g., leakage caused by surge, overvoltage, or degradation of the clamping element 106). An event is considered to begin when the temperature of the voltage-clamping element rises at a rate greater than the predetermined threshold over a predetermined time period. The processing device 202 also can calculate the overvoltage magnitude, AC and DC current caused by overvoltage, and AC and DC leakage current.

The ambient temperature T_{A} may optionally be used to assist in determining the original starting point of temperature changes during events, or to help identify whether small T_{M} fluctuations are caused by changes in ambient temperature. When utilizing only T_{M}, the peak surge current as well as the number of surges can be determined. Surge events can be characterized by the temperature of the voltage-clamping element 106 reaching a peak value within 30 seconds after the initial temperature rise (typically 10-15 seconds).

Additionally a prediction can be made with respect to if the thermal disconnect element 108 has or will disconnect the voltage-clamping element 106 from the terminal 112. When monitoring both T_{M} and T_{A} and their changing pattern over time, the overvoltage magnitude, AC current, DC current caused by the overvoltage, and the AC and DC leakage currents can be calculated. When monitoring T_{M}, T_{A}, the changing pattern over time plus an additional operating voltage, the process of determining the above parameters can be significantly simplified.

When analyzing the temperature data, to distinguish between an overvoltage event, a surge event, or a degraded (leaking) voltage-clamping element, the device and method can calculate the overvoltage amplitude, the current caused by overvoltage, the peak surge current, the number of surges and their scale, and the leakage current caused by the degraded voltage-clamping element. A percentage of the total life of the voltage-clamping element 106 that was consumed by the event then can be displayed along with the total remaining life of the voltage-clamping element 106. Such information can be displayed, for example, as a percentage. If the remaining life of the voltage-clamping element 106 drops below a predetermined threshold level, an alarm can be generated to alert maintenance personnel that the voltage-clamping element should be replaced.

The device and method operate based on the knowledge that part of the energy absorbed by the voltage-clamping element 106 creates a temperature rise in the voltage-clamping element. The temperature rise can be calculated using the specific heat and energy transfer of the voltage-clamping element 106, as shown in Equation 1 (which is a re-written form of the formula for specific heat capacity),

$$Δ T = Q / ( c * m ) \qquad Equation 1$$

where
ΔT is the change in temperature in Kelvin,
Q is the heat energy in Joules,
c is the specific heat in J/Kg·K, and
m is the mass of the voltage-clamping element in Kg.

Additionally, the ambient temperature T_{A} can be used as a benchmark to reveal that small changes in T_{M} are based on the energy transfer of a surge or overvoltage event, rather than environmental changes. It has been found that T_{M}, T_{A} and their changes caused by leakage, surge events and overvoltage events show different patterns over time. In view of this, the electric parameters of the voltage-clamping element 106 or parameters of the event can be determined based on these patterns.

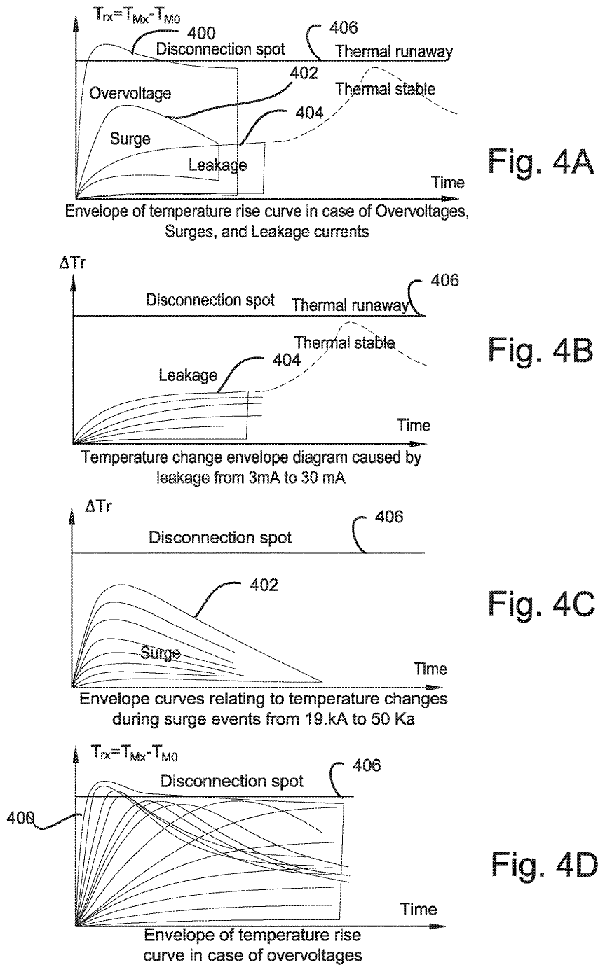

FIGS. 4A-4D illustrate patterns for T_{M} and T_{A} over time for one type of voltage-clamping element 106. As will be appreciated, different voltage-clamping elements may have different patterns. FIG. 4A is a graphical illustration showing the T_{M} envelope (Trx=T_{Mx}−T_{M0} over time for various events, namely, an overvoltage event 400, a surge event 402, and leakage 404 of a degraded voltage-clamping element 106, while FIGS. 4B-4D illustrate exemplary curves for leakage 404, surge event 402 and overvoltage event 400. As can be seen in FIGS. 4A-4D, an overvoltage event 400 has a very fast rise time compared to a surge event 402 and to leakage 404. Also, and as best seen in FIG. 4D, some of the patterns for an overvoltage event 400 rise above the disconnection limit 406, at which point the thermal protection element 108 disconnects the voltage-clamping element 106 from the terminal 112. Additionally, as seen in FIG. 4B the leakage 404 for the degraded voltage-clamping element 106 increases as the overvoltage event 400 or surge event 402 peaks, after which the leakage remains relatively constant despite the overvoltage event 300 and surge event 302 subsiding. This constant leakage 404 is due to degradation of the voltage-clamping element 106. FIG. 4B relates to thermal stability and runaway corresponding to TPMOV end-of-life alarm. The increase in leakage current will eventually lead to thermal runaway of the TPMOV. Prior to TPMOV thermal runaway, it is characterized by an increasingly faster slope of increasing leakage current.

It is noted that the rise in temperature of the voltage-clamping element 106 is slower than the corresponding energy absorption events. As a result, the event can be recognized only after it has occurred, as the energy takes time to heat the voltage-clamping element 106 and transfer the heat to the measurement point (i.e., the region monitored by the temperature sensor 114). For example, after applying a 20 kA 8/20 μs surge, the temperature of the voltage-clamping element 106 may peak 10-15 seconds after the surge. Due to this slow response, extremely large surges or extremely high overvoltages cannot be determined because such extreme events will cause the thermal protection element 108 to disconnect the voltage-clamping element 106 in a very short time (for example, 1 second). Using non-electrical parameters such as temperature to calculate electrical parameters (current or voltage), in and of itself, may not be very accurate. However, it is precisely because of this slow response that a substantial amount of meaningless instantaneous electrical parameter information can be filtered out, thus simplifying the entire monitoring process.

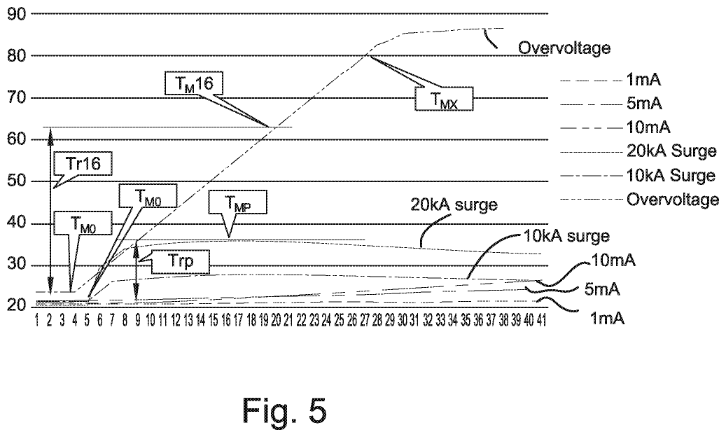

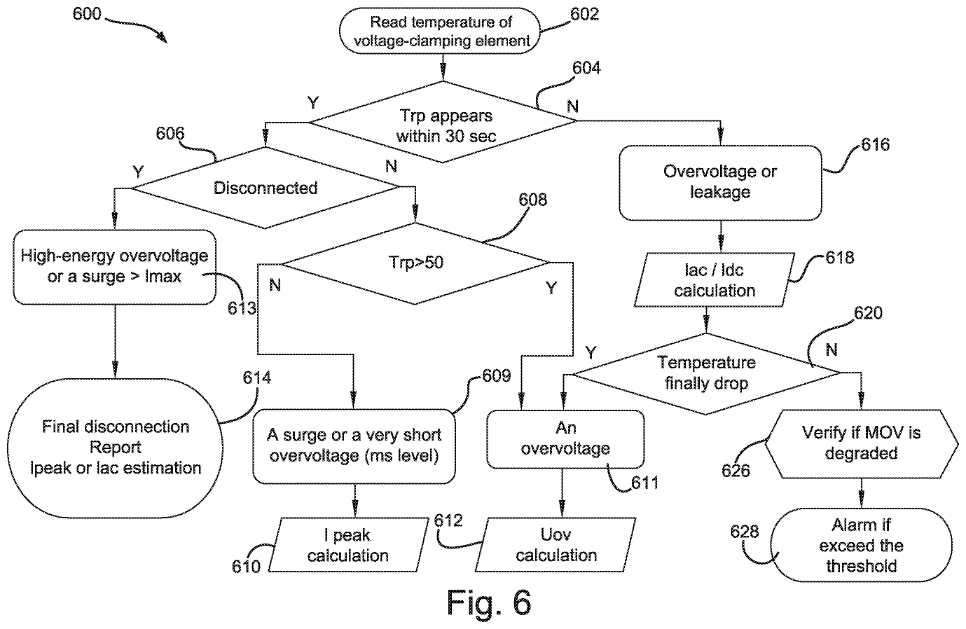

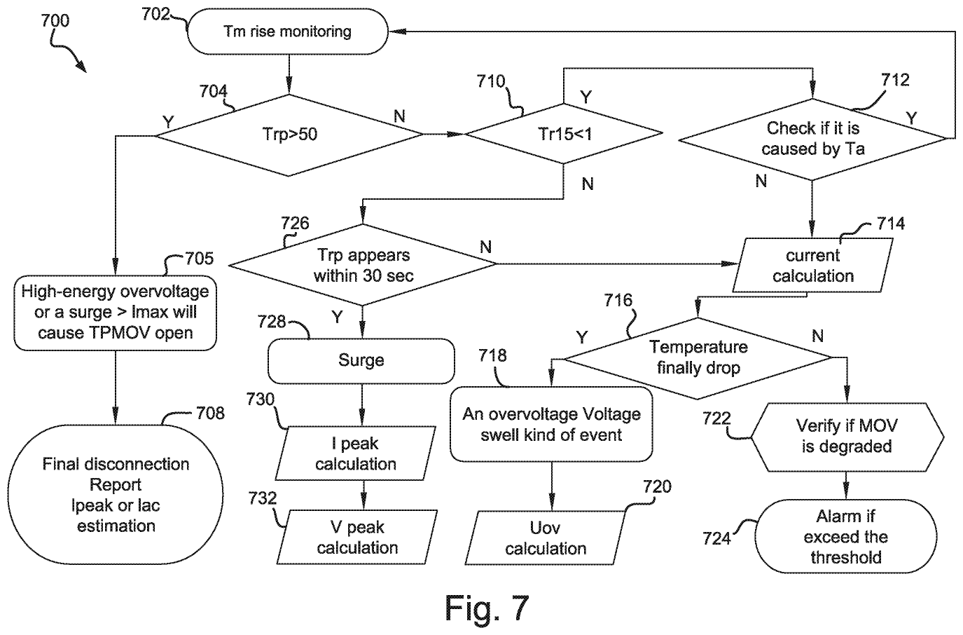

In order to clearly explain how to calculate the electrical parameters of the voltage-clamping element 106 as referenced in the flow charts of FIGS. 6 and 7, the parameters T_{M}, T_{A} and Tr are utilized.
T_{M0} is the initial temperature in degrees C. of the voltage-clamping element 106 prior to undergoing an event that causes temperature rise
T_{A} is ambient temperature in degrees C. at the voltage-clamping element 106.
Tr is the difference between T_{M} and T_{M0} measurement in degrees C.,
Trx is the temperature rise and is calculated as the difference between T_{Mx} and T_{M0} at x seconds after the event begins (i.e., T_{Mx}−T_{M0}) in degrees C.,
T_{Mp} is the peak temperature in degrees C. of the voltage-clamping element 106
Trp is the peak temperature rise and is obtained from the difference between T_{Mp} and T_{M0} (i.e., T_{Mp}−T_{M0}) in degrees C.
Tdiff is the difference between T_{M0} and T_{A0} (i.e., T_{M0}−T_{A0}) in degrees C.
   FIG. 5 graphically illustrates exemplary parameters for different events.

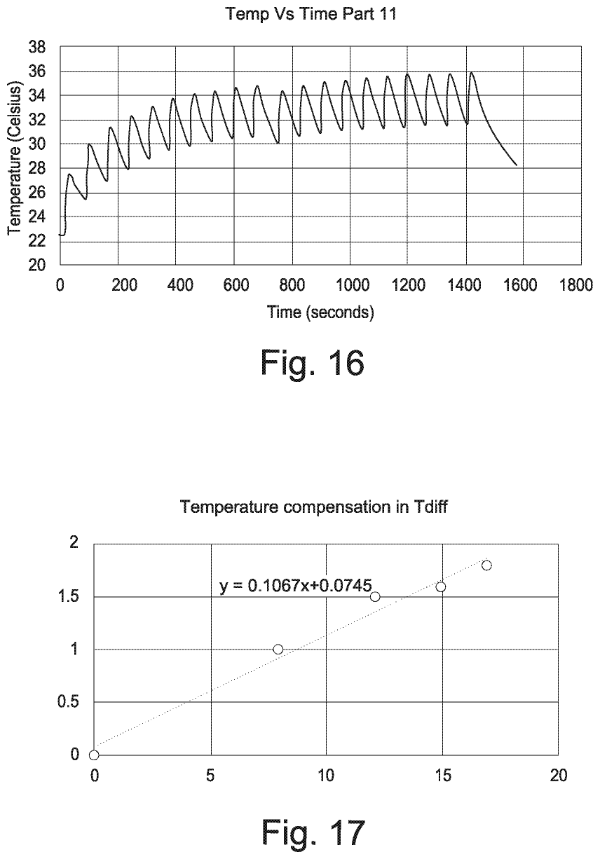

The surge current absorbed by the voltage-clamping element 106 during a surge event can be calculated based on Equations 2 and 3,

$${T}^{′} = T r p + c * Tdiff \qquad Equation 2$$

$$Ipeak ( 8 / 20 u s ) = a * ( {T}^{′ b} ) \qquad Equation 3$$

where
T′ is the temperature rise in degrees C. after temperature compensation (when a surge event occurs under the condition of T_{M}>T_{A}, compensation may be performed for heat dissipation during the measurement process),
Tdiff=T_{M0}−T_{A0},
Trp=T_{Mp}−T_{M0},
Ipeak is the peak surge current in amps through the voltage-clamping element 106 for an 8/20 us test signal, and
a, b, and c are coefficients that change based on the specific type of voltage-clamping element 106 (the coefficients are discussed in further detail below).
   While equation 3 utilizes T′, it is noted that the peak temperature rise Trp can be used in place of T′ in equation 3, although accuracy may decrease (using T′ can improve accuracy of Ipeak when T_{M} and T_{A} are not equal). FIGS. 16 and 17 (discussed below) are a source for Equations 3 and 2, respectively. As an alternative to Equation 2, the temperature of the voltage-clamping element 106 at a specific point in time (i.e., T_{Mx}) can be used to calculate the peak value of the surge. This is shown in Equation 4,

$${T}^{′} = Trx + b * Tdiff \qquad Equation 4$$

where T′, Trx and Tdiff are as defined above, and b is a coefficient corresponding to the specific voltage-clamping element 106.

The AC and DC overvoltage magnitude applied to the voltage-clamping element 106 can be calculated based on Equation 5

$$Uov = a * V 1 mA * Trx \hat{} b \qquad Equation 5$$

where
Tᵣₓ is the T_{M} measurement x seconds from the beginning of the event (e.g., Tᵣ₆₀=T_{M60}−T_{M0}, Tᵣₓ=T_{Mx}−T_{M0}) in degrees C.,
Uov is the AC or DC overvoltage magnitude in volts
V1 mA is a measured value for the voltage-clamping element 106 provided by the voltage-clamping element manufacturer (the overvoltage magnitude depends on individual voltage-clamping element). Specifically, V1 mA is the voltage at which the voltage-clamping element conducts a clamping current of 1 mA. In other words, when the voltage across the voltage-clamping element reaches the V1 mA value, the voltage-clamping element starts to conduct and limits the voltage to protect the connected circuit (also called breakdown voltage). Preferably, V1 mA is the real (actual) measurement for the voltage-clamping element (i.e., not nominal value) to enhance accuracy, although the nominal value may be used if a measured value for V1 mA is not available.
a and b are coefficients of the specific voltage-clamping element.
   It is noted that the overvoltage magnitude calculation result is applied to both ends of the voltage-clamping element, not the value on the entire system. More specifically, due to the impedance of the wires connected to the voltage-clamping element and the resulting voltage drop across the wires, the voltage across the voltage-clamping element is slightly different (lower) than the voltage across the whole system (i.e., the voltage-clamping element plus the wires). The total voltage across the voltage-clamping element is the voltage across the voltage-clamping system minus the voltage drop across the wires. This difference can be significant when the current flowing through the voltage-clamping element is large or the wire resistance connected to the voltage-clamping element is high. The main reason for this is that when the voltage-clamping element conducts current, the voltage-clamping element resistance can be very small, <1 ohm, which will highlight the wire resistance.

The overvoltage AC/DC current through the voltage-clamping element 106 may be calculated using Equation 6,

$$Iov = a * Trx + b \qquad Equation 6$$

where
Iov is the current through the voltage-clamping element in amps
Trx is the difference between T_{M} and T_{M0} x seconds after the event begins (i.e, T_{Mx}−T_{M0}) in degrees C.
a and b are coefficients of the specific voltage-clamping element 106.

Leakage current through the voltage-clamping element 106 is caused by degradation of the voltage-clamping element 106. Regardless of whether the voltage-clamping element is degraded, the temperature rise of the voltage-clamping element 106 is mainly related to the magnitude of the current. The AC and DC leakage current can be estimated using Equations 7.

$$IL = a * Trx + b \qquad Equation 7$$

where
IL is the leakage current of the voltage-clamping element in amps
Trx is the difference between T_{M} and T_{M0} x seconds after the event begins (i.e, T_{Mx}−T_{M0}) in degrees C.
a and b are coefficients of the specific voltage-clamping element 106.

There are several overlapping areas, namely, very short moderate overvoltages and surges, and very low overvoltages and leakage. However, with a thermal protection element 108 in series with the voltage-clamping element 106, these areas can be recognized. Key differences are:
Larger overvoltage events will cause the thermal protection element 108 to disconnect the voltage-clamping element 106, while a surge event in the design range of the voltage-clamping element 106 will not cause such disconnect;
Low or moderate overvoltage events may result in T_{M} peaking 30 seconds or more after the event has occurred (the time varies based on the specifics of the voltage-clamping element 106);
Over time, the overvoltage event will eventually disappear, but the current leakage will remain.

A surge event is manifested as an instantaneous large energy release process, which causes the temperature of the voltage-clamping element 106 to reach a peak in a short time (10-30 seconds) and, unless the surge exceeds the maximum design of the voltage-clamping element, the temperature gradually decreases to return to normal. An overvoltage event is manifested as the continuous generation of huge energy, which may cause the thermal protection element 108 to open and remove the voltage-clamping element from power. During an overvoltage event, T_{M} may reach T_{Mp} within 20 seconds after being disconnected from power, while lower overvoltage events, in the short term, produce thermally stable events that take longer to peak. Leakage current is manifested as the continuous accumulation of low energy that eventually tends to be thermally stable, causing the thermal element to disconnect after a long period of time.

In addition to detecting individual events, multiple simultaneous events can also be detected by comparing the temperature rising rate and falling rate after the surge event. For example, if a surge event and a leakage event occur at the same time, then the following can be surmised
If the temperature of the voltage-clamping element 106 continues to rise, the rate of change in the temperature indicates the level of leakage (either stable or runaway).
If the temperature stabilizes, this indicates a thermal stable state at a certain leakage level.
If the temperature decreases, the peak temperature of the surge has exceeded the temperature at which the leakage level may produce thermal stability.
If a surge occurred during an overvoltage event, it can be considered a larger overvoltage event or a larger surge event depending on whether the temperature peak occurs within 30 seconds.
   The above information can be used to recognize the event to distinguish if the event is leakage, a surge, or an overvoltage.

For example, and with reference to FIG. 6, flow chart 600 illustrates exemplary steps in accordance with one embodiment of the invention for recognizing the type of event that the voltage-clamping element 106 has undergone. The steps of flowchart 600 may be executed, for example, by the processing device 202. Additionally, it is noted that the various calculations referenced in the flow chart 600 will be discussed in further detail below. While a specific order of steps is illustrated in this flow chart, it will be understood that some steps may be performed in a different order without departing from the scope of the invention. The same applies for each of the flow charts discussed below.

Beginning at step 602, the processing device 202 reads the temperature of the voltage-clamping element 106 as measured by the temperature sensor 114 to determine the temperature rise of the voltage-clamping element 106, and at step 604 the processing device 202 determines if the measured temperature has reached a peak within a predetermined period, e.g., 30 seconds or less; the actual time period may vary depending on the type of voltage-clamping element. If the temperature of the voltage-clamping element 106 has peaked in 30 seconds or less, the method moves to step 606 and the processing device 202 determines a state of the thermal protection element 108. For example, the processing device 202 can monitor the status indicator 109 to determine if the thermal protection element 108 is in the normal or tripped (disconnected) state. If the thermal protection element 108 is in the normal (connected) state, the method moves to step 608 where the processing device compares the time required to reach peak temperature to a predetermined value, e.g., 50 seconds. If the time to reach peak temperature is less than or equal to the predetermined value, the method moves to step 609 where the processing device concludes that voltage-clamping element 106 has experienced a surge event or a very short overvoltage event (millisecond level). The method then moves to step 610 where the processing device calculates the peak current during the event. Moving back to step 608, if the time to reach peak temperature is greater than the predetermined value, then the method moves to step 611 where the processing device 202 concludes that the voltage-clamping element 106 has experienced an overvoltage event. The method then moves to step 612 where the processing device 202 estimates the magnitude of the overvoltage event.

Moving back to step 606, if it is determined that the thermal protection element 108 has disconnected the voltage-clamping element 106 (as detected by the status indicator 109), then the method moves to step 613 where the processing device 202 concludes that the voltage-clamping element has experienced a high-energy overvoltage event or a surge event exceeding a maximum current of the voltage-clamping element 106. The method then moves to step 614 where the processing device 202 issues a disconnection report for the voltage-clamping element 106 along with an estimation of the peak current (e.g., Equation 3) and/or the estimated current (e.g., Equation 6) as discussed herein.

Moving back to step 604, if the peak temperature of the voltage-clamping element 106 occurs after 30 seconds, then the method moves to step 616 where the processing device 202 concludes the voltage-clamping element has experienced an overvoltage event or leakage is present in the voltage-clamping element 106, and at step 618 the processing device 202 estimates the AC current and/or DC current (e.g., Equation 6) absorbed by the voltage-clamping element 106 as discussed herein. Next at step 610 the processing device 202 checks if the measured temperature of the voltage-clamping element 106 eventually drops. If the temperature of the voltage-clamping element 106 does drop, then the method moves back to step 611 where the processing device 202 concludes the voltage-clamping element 106 has experienced an overvoltage event, and at step 612 the processing device 202 estimates the magnitude of the overvoltage event (e.g., Equation 5).

Moving back to step 610, if the temperature of the voltage-clamping element 106 does not drop, then at step 616 the processing device 202 verifies if the voltage-clamping element has degraded (i.e., leakage). At step 618 the leakage current is calculated (e.g., equation 7) and if the leakage current exceeds a predetermined threshold, the processing device 202 generates an alarm.

Moving now to FIG. 7, illustrated is another flowchart 700 illustrating exemplary steps in accordance with another embodiment of the invention for recognizing the type of event that the voltage-clamping element 106 has undergone. Like to flowchart 600 of FIG. 6, the steps of flowchart 700 may be executed by the processing device 202, and the order of steps may be altered from that which is illustrated.

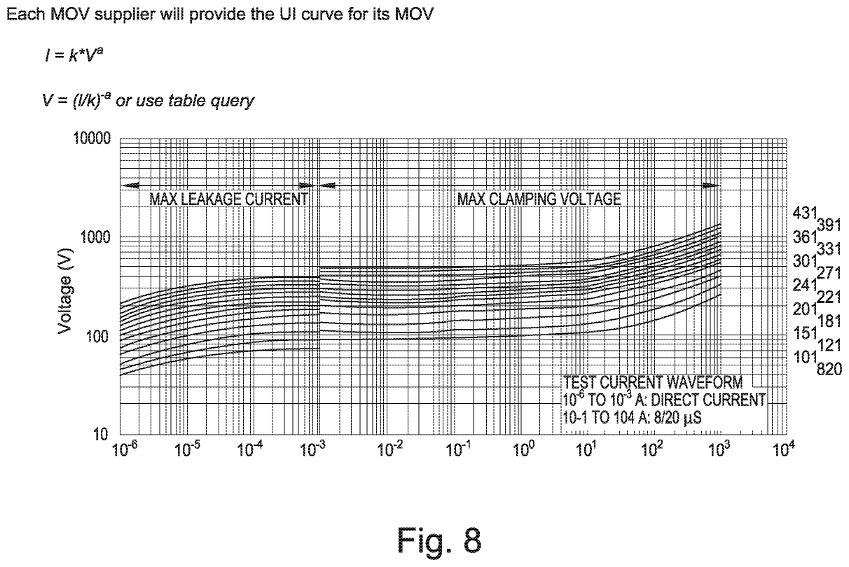

The method of FIG. 7 is based on using the temperature change from the beginning of the 15^{th} second after the event begins, and the voltage-clamping element's U/I curve and current calculation results are used to calculate the voltage. FIG. 8 illustrates an exemplary UI curve for a voltage-clamping element in the form of an MOV. As will be appreciated, different curves are utilized for different types of voltage-clamping elements.

Beginning at step 702, the processing device 202 reads the temperature of the voltage-clamping element 106 as measured by the temperature sensor 114 and determines the temperature rise for a predetermined time after the event begins (e.g., 15 seconds). At step 704 the processing device 202 determines if the temperature rise Tᵣ fifteen seconds after the event begins (Tr₁₅) is greater than 50 degrees C. If after fifteen seconds the temperature rise Tr₁₅ of the voltage-clamping element is 106 is greater than 50 degrees C., the method moves to step 706 where it is concluded that the voltage-clamping element 106 experienced a high-energy overvoltage event or a surge event that caused or causes the thermal protection element 108 to open and disconnect the voltage-clamping element 106. The method then moves to step 708 where the peak current and/or the AC current (e.g., Equation 6) is calculated as discussed in further detail below.

Moving back to step 704, if after fifteen seconds the temperature rise Tr₁₅ of the voltage-clamping element 106 is not greater than 50 degrees C., the method moves to step 710 where the processing device 202 determines if the temperature rise of the voltage-clamping element 106 after fifteen seconds is less than 1 degree C. If the temperature rise Tr₁₅ of the voltage-clamping element 106 is less than 1 degree C., the method moves to step 712 where the processing device 202 checks if the temperature rise Tr₁₅ was caused by the ambient air. In this regard, the processing device 202 may compare the ambient air temperature T_{A} as determined from sensor 210 and the voltage-clamping element temperature T_{M} and determine if they track each other. If T_{M} tracks T_{A}, then it is concluded the temperature rise of the voltage-clamping element 106 was due to the ambient temperature and the method moves back to step 702. However, if the temperature rise was not caused by the ambient air temperature, the method moves to step 714 where the processing device 202 calculates the current (e.g., surge current) through the voltage-clamping element. Next at step 716 the processing device 202, after a predetermined interval (e.g., a few seconds to tens of seconds), determines if the temperature T_{M} of the voltage-clamping element 106 has dropped. If the temperature has dropped, the method moves to step 718 where the processing device 202 concludes that an overvoltage swell event has occurred and at step 720 the processing device 202 calculates the magnitude of the overvoltage event (e.g., Equation 5).

Moving back to step 716, if the processing device 202 determines that the temperature of the voltage-clamping element 106 has not dropped, then the method moves to step 722 where the processing device 202 verifies if the voltage-clamping element 106 has degraded (e.g., excessive leakage current) and, if that degradation exceeds a predetermined threshold, at step 724 the processing device 202 issues an alarm that the voltage-clamping element should be replaced. In determining if an alarm should be generated, the processing device 202 calculates the leakage current (e.g., Equation 7) for the voltage-clamping element 106 and compares the calculated leakage current to a threshold value. If the calculated leakage current exceeds the threshold value, the alarm is generated.

Moving back to step 710, if the processing device 202 determines the temperature rise Tr₁₅ of the voltage-clamping element 106 is not less than 1 degree C., the method moves to step 726 where the processing device 202 determines if the temperature of the voltage-clamping element 106 peaks (Trp) within 30 seconds after the event begins (Trp is the peak temperature rise during the change of T_{M}). If the temperature of the voltage-clamping element 106 has peaked within 30 seconds after the event begins, the method moves to step 728 where the processing device 202 concludes the voltage-clamping element 106 has experienced a surge event, and at steps 730 and 732 the processing device 202 calculates the peak current (e.g., Equation 3) and peak voltage (e.g., Equation 5) experienced by the voltage-clamping element 106. Moving back to step 726, if the temperature of the voltage-clamping element 106 has not peaked within 30 seconds after the event begins, the method moves to step 714 as discussed above.

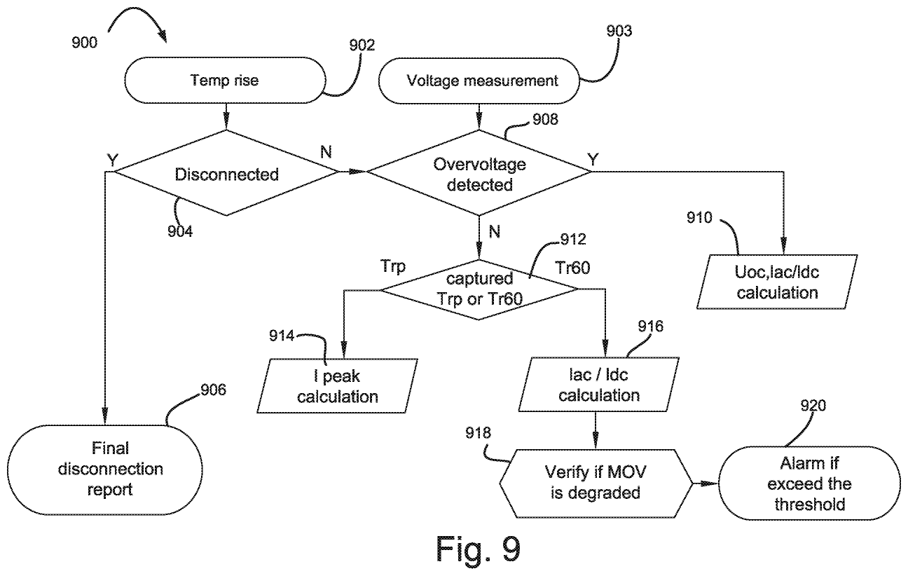

If the actual working voltage of the voltage-clamping element 106 and the ambient temperature T_{A} are measured at the same time of the event, the various parameters discussed above can be calculated more efficiently, as discussed in more detail with respect to FIG. 9.

FIG. 9 is a flow chart 900 illustrating exemplary steps for recognizing the type of event that the voltage-clamping element 106 has undergone along with voltage measuring. The steps of flowchart 900 may be executed by the processing device 202. Beginning at steps 902 and 903, the processing device 202 reads the temperature of the voltage-clamping element 106 as measured by the temperature sensor 114 to determine the temperature rise and also measures the voltage at the voltage-clamping element. At step 904 the processing device 202 determines a state of the thermal protection element 108. For example, the processing device 202 can monitor the status indicator 109 to determine if the thermal protection element 108 is in the normal or tripped (disconnected) state. If the thermal protection element 108 is in the disconnected (tripped) state, the method moves to step 906 where the processing device 202 issues a disconnection report (e.g., an alarm) for the voltage-clamping element 106 along with an estimation of the peak current (e.g., Equation 3) and/or the estimated AC current (e.g., Equation 6) of the voltage-clamping element 106 during the event.

Moving back to step 904, if the thermal protection element 108 is in the normal (connected) state, the method moves to step 908 where the processing device 202 determines if an overvoltage event has occurred. For example, the processing device 202 may use the voltage measured at step 903 and compare the measured voltage to a threshold value to determine if an overvoltage has occurred. Alternatively, the processing device 202 may check the temperature of the voltage-clamping element 106 and if the temperature initially increased at or greater than a predetermined rate, peaked within a specified time period after the event began (e.g., less than 60 seconds), and then dropped, the processing device 202 may conclude that an overvoltage event has occurred. If the temperature did not drop but instead remained elevated, then the processing device may conclude that the voltage-clamping element is leaking current and thus has degraded. If the processing device 202 concludes an overvoltage event has occurred, then the method moves to step 910 where the processing device 202 calculates the magnitude of the overvoltage event (e.g., Equation 5) and also the AC and DC current (e.g., Equation 6) through the voltage-clamping element 106.

Moving back to step 908, if the processing device 202 concludes that an overvoltage event has not occurred, then the method moves to step 912 where the processing device 202 determines if the temperature of the voltage-clamping element 106 has peaked within 60 seconds (or some other predetermined time period). If the temperature has peaked within 60 seconds, then the method moves to step 914 where the processing device 202 calculates the peak current through the voltage-clamping element 106 (e.g., Equation 3). If the temperature has not peaked within 60 seconds, then the method moves to step 916 and the processing device 202 uses the temperature as measured 60 seconds after the temperature began to rise (i.e., Tᵣ₆₀) to calculate the AC and DC current (e.g., Equation 6) through the voltage-clamping element 106. Next at step 918 the processing device verifies if the voltage-clamping element has degraded, for example, by determining if the AC or DC leakage current exceeds respective predetermined threshold values and if so, concludes the voltage-clamping element 106 has degraded. At step 920 the processing device 202 generates an alarm if the AC and/or DC leakage current exceeds the predetermined thresholds.

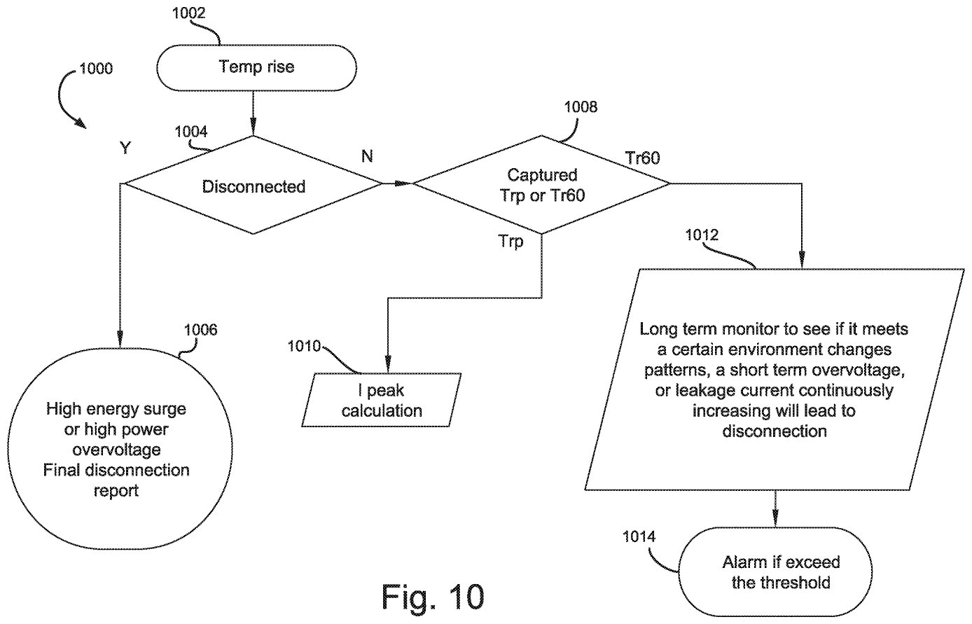

If the ambient temperature T_{A} is not available, it cannot be ascertained if an environment change, a low overvoltage or increasing leakage current (due to degradation) has caused the temperature of the voltage-clamping element to increase. However, information concerning the voltage-clamping element 106 still can be ascertained, albeit with a decrease in accuracy. More particularly, the peak current of surge or instantaneous high-energy overvoltage can be calculated (based on a specific waveform, without temperature compensation). Also, prior to failure an alarm can be generated indicating that the voltage-clamping element 106 is near the end of life. Further details are discussed below with respect to FIG. 10.

Referring to FIG. 10, illustrated is a flow chart 1000 showing exemplary steps for recognizing the type of event that the voltage-clamping element 106 has undergone, without using the ambient temperature T_{A} to detect such events. The steps of flowchart 1000 may be executed by the processing device 202. Beginning at step 1002, the processing device 202 reads the temperature of the voltage-clamping element 106 as measured by the temperature sensor 114 and determines the temperature rise. Next at step 1004 the processing device 202 determines if the thermal protection element 108 has tripped and disconnected the voltage-clamping element 106 from the circuit. In this regard, the processing device 202 may determine the thermal protection element 108 has disconnected the voltage-clamping element based on a status of the indicator 109. If the processing device 202 determines the thermal protection element 108 has disconnected the voltage-clamping element 106, the method moves to step 1006 where the processing device 202 concludes the voltage-clamping element 106 was subjected to a high energy surge or high power overvoltage event, and issues a final disconnection report, e.g., audible alerts, summary of events experienced by the voltage-clamping element, etc.

Moving back to step 1004, if the processing device 202 concludes the voltage-clamping element 106 has not been disconnected, the method moves to step 1008 where the processing device 202 determines if the temperature of the voltage-clamping element 106 has peaked within 60 seconds after the event began. If the temperature of the voltage-clamping element 106 did peak within 60 seconds, the method moves to step 1010 where the processing device calculates the peak current (e.g., Equation 3) through the voltage-clamping element during the event. Moving back to step 1008, if the temperature of the voltage-clamping element 106 did not peak within 60 seconds after the event began, the method moves to step 1012 where the processing device 202 monitors the voltage-clamping element 106 over a predetermined “long” term to determine the degradation of the voltage-clamping element. More specifically, increase in leakage current may not reach the level of one-step degradation and may last for a month or more. The rate of increase of the leakage current can be monitored at specified intervals (e.g., once per day). If a slope of the rate of increase of the leakage current is greater than a first predetermined threshold, then it is likely the voltage-clamping element will fail in the very near future. If the slope of the rate of increase of the leakage current is less than the first predetermined threshold but greater than a second predetermined threshold, then the voltage-clamping element, while degraded, is likely to continue to operate for some period of time. Based on the value of the slope, it can be estimated how long the voltage-clamping element will continue to operate before failing. The method then moves to step 1014 where the processing device 202 issues an alarm if a threshold (e.g., the slope of the rate of increase of leakage current) is exceeded. It is noted that while the method of FIG. 10 utilizes only the temperature of the voltage-clamping element to execute the method, the ambient temperature, if available, may also be measured and used to enhance accuracy of the calculations.

In accordance with an aspect of the invention, a method for estimating an amount of life of a voltage-clamping element consumed due to an electrical event subjected to the voltage-clamping element is provided, where the estimation is based on temperature measurements of the voltage-clamping element. More specifically, a temperature rise of the voltage-clamping element due to the electrical event is determined, for example, based on a temperature of the voltage-clamping element just prior to the event and a temperature of the voltage clamping element during or subsequent to the event (e.g., a predetermined time after the event has begun). Based on the temperature rise of the voltage-clamping element, and as will be described in more detail below, a pulse energy absorbed by the voltage-clamping element due to the electrical event is determined. The amount of life of the voltage-clamping element consumed due to the electrical event is determined based on the pulse energy absorbed by the voltage-clamping element and energy absorption characteristics of the voltage-clamping element.

The energy absorption characteristics of the voltage-clamping element may be determined, for example, by converting electrical specifications of the voltage-clamping element to an energy absorption curve representing an amount of energy the voltage-clamping element can absorb. A remaining life of the voltage clamping element can be determined based a difference between a maximum energy absorption of the voltage-clamping element, which may be obtained from specifications of the voltage-clamping element, and the total energy absorbed by the voltage-clamping element.

In determining the remaining life of the voltage-clamping element, since different surge/overvoltage pulse widths affect the life of the voltage-clamping element, a life prediction method can be divided into optimistic prediction, balanced prediction and pessimistic prediction. Users can apply different forecasts based on the importance of their facilities.

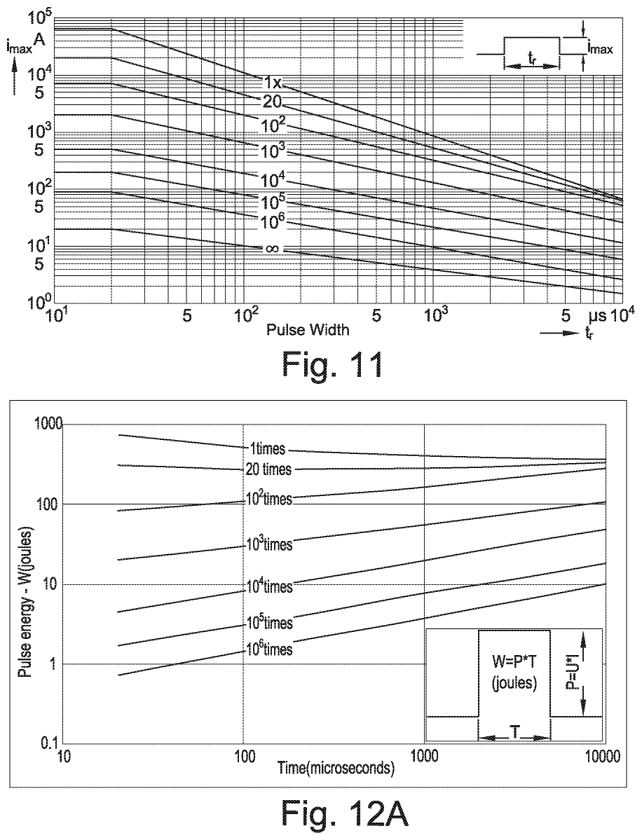

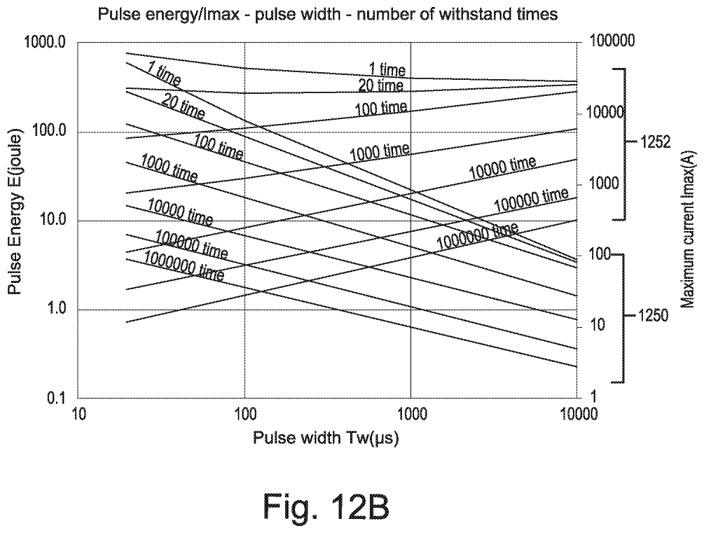

Voltage-clamping element suppliers provide a derating curve, which represents the relationship between the number of overvoltage square waves, pulse width of the overvoltage square wave and/or the pulse width and current that the voltage-clamping element can effectively withstand. FIG. 11 illustrates an exemplary de-rating curve for a specific voltage-clamping element. For thermally protected voltage-clamping elements, when only temperature of the device is measured (i.e., ambient is not measured), the pulse width cannot be detected or calculated, which can make it difficult to accurately predict the remaining life of the voltage-clamping element. Even if the current can be calculated, without the pulse width the predictions will be crude and less reliable. The temperature measurement perfectly avoids this problem by using pulse energy and withstand times. Using Equation 8, the de-rating curve can be converted into a new chart of the pulse energy-number of pulses, which is illustrated in FIG. 12A

$$Q = U \cdot {i}_{max} \cdot {t}_{r} \qquad Equation 8$$

where
Q is the energy in Joules,
iₘₐₓ is the pulse current in amps,
tᵣ is the pulse width in seconds,
U is the voltage across the voltage clamping element in volts when imax passes through the voltage-clamping element (can be obtained from FIG. 8)
   Equation 8 can be used to convert the data of FIG. 11, which is provided by the manufacturer of the voltage-clamping element, to FIG. 12A. FIG. 11 indicates the maximum current and number of square waves of pulse width allowed by the voltage-clamping element. For example, and with reference to FIG. 11, for an event having a pulse width of 100 micro seconds, the voltage-clamping element can withstand a pulse current (iₘₐₓ) of approximately 2120 amps for about 100 events, while for an event having a pulse width of 1000 micro seconds, the voltage-clamping element can withstand a pulse current (iₘₐₓ) of approximately 380 amps for about 100 events. Similarly, for an event having a pulse width of 100 micro seconds, the voltage-clamping element can withstand a pulse current (iₘₐₓ) of approximately 37 amps for about 1,000,000 events, while for an event having a pulse width of 1000 micro seconds, the voltage-clamping element can withstand a pulse current (iₘₐₓ) of approximately 10 amps for about 1,000,000 events. As will be appreciated, additional pulse current data points can be obtained based on different pulse widths and different numbers of events to obtain a characteristic table of data points for the specific voltage-clamping element. This table of data points then can be used to determine the maximum pulse energy that the voltage-clamping element can absorb. More specifically, the pulse energy that can be absorbed by the voltage-clamping element can be derived using the obtained table of data points in combination with Equation 8 and solving for Q. By solving for a number of data points, a pulse energy curve for the specific voltage-clamping element. FIG. 12A illustrates a pulse energy curve for an exemplary voltage-clamping element, where FIG. 12A was derived based on the above methodology.

Referring briefly to FIG. 12B, lines 1250 are the de-rating curve (tolerable quantity) of pulses with different widths at different Ipeak (A) currents. Lines 1252 are the pulse energy curve (tolerable quantity) of pulses with different pulse widths and different pulse energies (Joules). The first (top) de-rating curve 1250 represents a situation in which the voltage-clamping element can withstand the impact of one square wave. When the pulse width is 20 us, the maximum square wave current is 40 kA, and when the pulse width is 2000 us or 2 ms, the maximum square wave current is only 0.4 kA. In other words, a square wave with a pulse width of 20 us and 40 kA or a square wave with a pulse width of 2000 us and 0.4 kA consumes 100% of the life of the voltage-clamping element. The pulse energy curve 1252 is a calculated energy de-rating curve and graph indicates the maximum energy and number of square waves of pulse width allowed by the voltage-clamping element. When the pulse width is 20 us, the maximum square wave energy is 737 J, and when the pulse width is 2000 us or 2 ms the maximum square wave energy is 391 J. (737 J and 391 J—refer to table 1). So 40 kA and 0.4 kA may have the same lifetime consumption when the pulses have different pulse widths. However, when switching to Energy, the difference between 40 kA and 0.4 kA is reduced to 737 J to 391 J. Accordingly, the effect of the pulse width T is minimized in this energy diagram. Since there is no way of knowing the exact pulse width of a live event, the current peaks cannot be used to predict the de-rating as the error would be too great. However, using the pulse energy to predict the de-rating, it becomes possible to predict the life consumption as the influence of the pulse width T is minimized (a change in pulse width by a factor of 100 (e.g., 20 us to 2000 us) produced only twice the energy change (from 737 to 391). Using the pulse energy greatly improves the reliability of predictions compared to using current alone. Surges or other overvoltages also can be identified based on the above scheme.

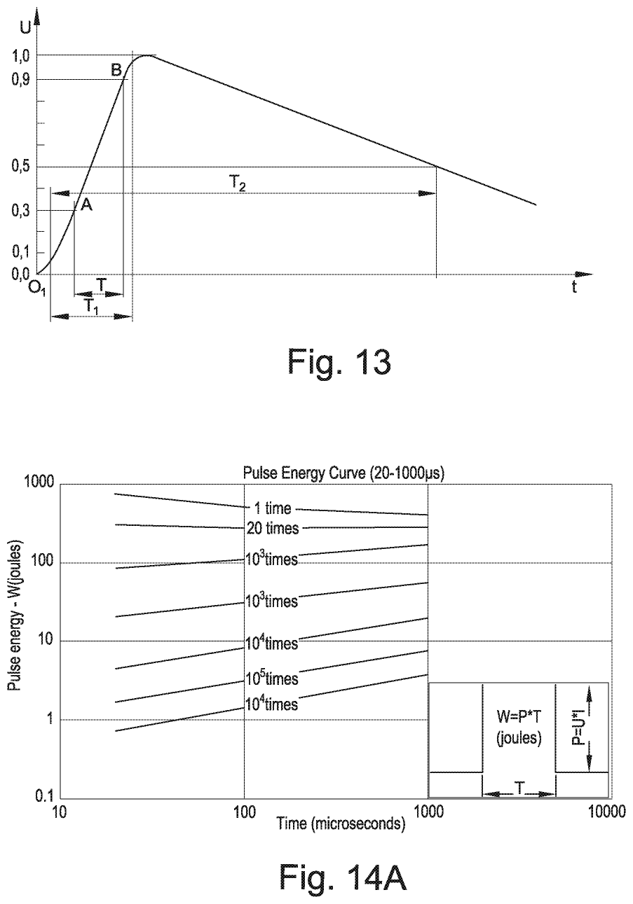

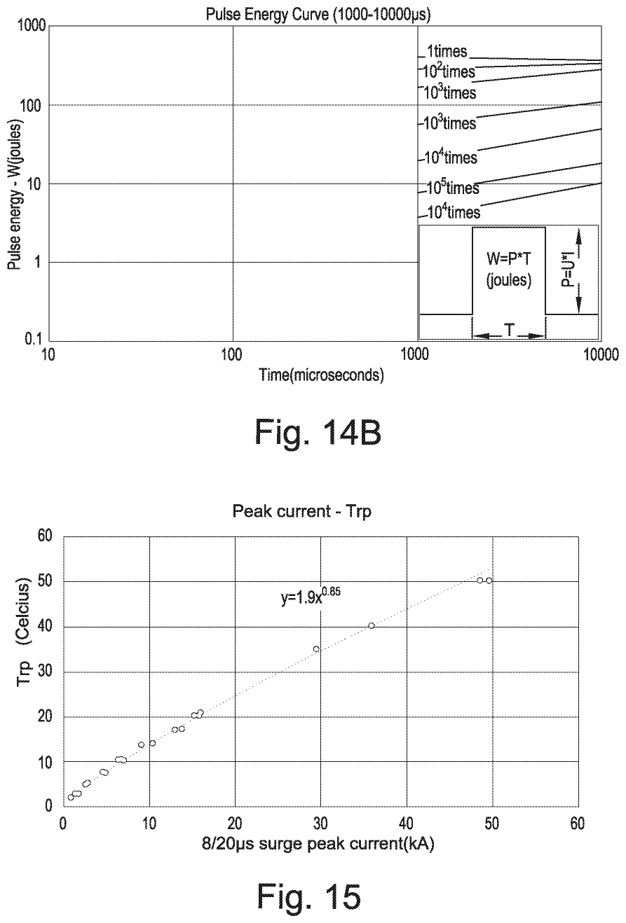

According to the definition of overvoltage, surge, etc., differences in pulse width exist between the respective parameters. The surge current can be used to calculate the life consumption of pulse energy with a width, for example, of 20-1000 μs, and other overvoltage energy can be used to calculate pulses with a width of 1000-10000 μs lifetime consumption of energy (different pulse width ranges may be used depending on the characteristics of the voltage-clamping element). A typical surge waveform is shown in FIG. 13, and except for severe overvoltage events caused by lightning or switching transients (which may cause direct disconnection of the voltage-clamping element), the most common wave tails (considered to be a pulse width) are between 20 ( 8/20 μs wave) to 1000 μs ( 10/1000 μs wave). Therefore, a 20-1000 μs, as illustrated in FIG. 14A, can be used for surge life consumption. For other types of overvoltages (except surges), energy pulses with a width of 1000-10000 μs, as illustrated in FIG. 14B, can also be used to calculate life consumption.

In accordance with an aspect of the invention, the temperature rise of the voltage-clamping element is measured, which represents energy absorption during the event. The energy then is broken down into surges or other over voltages, thereby greatly improving the reliability of predictions. In addition, users also can choose preset scenarios to enhance accuracy. For example, for systems installed within a building, all surge life consumption can be predicted using only 8/20 μs waves. Outdoor applications can be predicted using 10/350 μs waves.

To predict the lifetime consumption using event energy, the energy of the surge/overvoltage event is calculated. For example, a surge generates a temperature rise with a peak temperature rise value of Trp, and an oscilloscope can be used to capture the dynamic surge voltage (U) wave and the dynamic surge current (I) wave of the surge. Then the electric energy can be calculated by Equation 9,

$$Q = \int U \cdot I \cdot dt \qquad Equation 9$$

where
Q is the energy in Joules,
U is the dynamic surge voltage,
I is the dynamic surge current,
and dt represents an infinitesimal change in time, usually dependent on the oscilloscope frequency or the pulse width of the dynamic U, I measurements.
   Referring back to Equation 1 (ΔT=Q/cm), to avoid overly complicating the calculations by considering energy lost due to heat dissipation when temperatures reach peak temperatures, a series of experiments can be performed to capture the relationship between Trp and Q. From this, a new equation between Q and Trp, can be created, and curve fitting can be utilized to obtain the coefficients a and b based on Equations 10 and 11,

$$Qs = a * ( {Trp}^{b} ) \qquad Equation 10$$

$$Qs = a * ( {T}^{′ b} ) \qquad Equation 11$$

where
Qs is the energy in Joules,
Trp is the peak temperature rise in degrees C.,
T′ is the temperature rise in degrees C. after temperature compensation (when a surge event occurs under the condition of T_{M}>T_{A}, compensation may be performed for heat dissipation during the measurement process), and
a and b are coefficients of the voltage-clamping element.
   Alternatively, Equation 12, shown below, can be used to directly calculate the Q value from the previously calculated peak surge current Ipeak,

$$Qs = a * ( {Ipeak}^{b} ) \qquad Equation 12$$

where
Qs is the energy in Joules,
Ipeak is peak current in amps calculated from Equation 3, and
a and b are coefficients of the voltage-clamping element.

For voltage swells or other overvoltages, it is also possible to capture the relationship between Q and Trx, as shown in Equation 13

$${Q}_{TOTAL} = a * ( {Trx}^{b} ) \qquad Equation 13$$

where
Q_{TOTAL} is the energy in Joules,
Trx is the temperature rise x seconds after the event begins, and
a and b are coefficients of the voltage-clamping element.

An example is now illustrated using optimistic, balanced and pessimistic (OBP) prediction methodologies for the expected life of the voltage-clamping element. The OBP method focuses on the energy of the event and simply divides the pulse width of the event into two areas. Events with a pulse width of 20-1,000 μs are considered surge events, while events with a pulse width of 1,000-10,000 μs are considered overvoltage events. Table 1 below, which is obtained from FIG. 12A, illustrates the energy pulse width absorbed by the voltage-clamping element for various waveforms. Table can be used alone based on common events, such as surge life prediction for 8/20 μs pulses, or combined with various events with different pulse widths.

TABLE 1

| | Joules | | | | | |
|---|---|---|---|---|---|---|
| Pulse | Energy pulse width | | | | | |
| Number | 20 μs | 100 μs | 200 μs | 1000 μs | 2000 μs | 10000 μs |
| 1 | 737.6 | 514.2 | 469.1 | 401.3 | 391.3 | 365.4 |
| 20 | 308.5 | 272.3 | 276.9 | 282.3 | 297.9 | 335.7 |
| 100 | 84.7 | 109.3 | 123.3 | 167.5 | 197.0 | 280.9 |
| 1000 | 20.5 | 30.2 | 36.3 | 56.0 | 68.0 | 108.4 |
| 10000 | 4.5 | 8.3 | 10.8 | 19.8 | 26.5 | 49.1 |
| 100000 | 1.7 | 3.2 | 4.0 | 7.7 | 9.8 | 18.3 |
| 1000000 | 0.7 | 1.4 | 1.9 | 3.8 | 5.1 | 10.1 |

| | |
|---|---|
| For surge energy prediction | For overvoltage energy prediction |

Assuming a 20-1000 μs waveform width is used as the surge wave, a maximum energy of the 20-1000 μs waveform can be used for optimistic predictions, a minimum number of pulses for pessimistic predictions, and an average value for balanced predictions. For example, assuming a 20 μs width, the voltage-clamping element can withstand a single pulse having a maximum energy is 737.6 J (optimistic), 401.3 J (pessimistic), and 530.55 J (balanced). Similarly, assuming a 1000 μs width, the voltage-clamping element can withstand 100 pulses having a maximum energy of 167.5 J (optimistic), 84.7 J (pessimistic), or 121.2 J (balanced). Table 2 illustrates the number of pulses utilized for each prediction scenario (for each energy level).

TABLE 2

Joules
20-1000 μs surges

| Pulse number | optimistic | Balanced | pessimistic |
|---|---|---|---|
| 1 | 737.6 | 530.55 | 401.3 |
| 20 | 308.5 | 285 | 272.3 |
| 100 | 167.5 | 121.2 | 84.7 |
| 1000 | 56 | 35.75 | 20.5 |
| 10000 | 19.8 | 10.85 | 4.5 |
| 100000 | 7.7 | 4.15 | 1.7 |
| 1000000 | 3.8 | 1.95 | 0.7 |

For an overvoltage condition, a waveform width of 2000-10000 μs can be used. For an optimistic prediction, a maximum energy from 2000-10000 μs waveform can be used, for a pessimistic prediction a minimum number of pulses can be used, and for a balanced prediction an average value can be used for balanced prediction. Table 3 illustrates the number of pulses utilized for each prediction scenario (for each energy level). As will be appreciated, the width options can be adjusted to achieve different goals.

TABLE 3

Joules
1000-10000 μs Overvoltage

| Pulse number | Optimistic | Balanced | pessimistic |
|---|---|---|---|
| 1 | 401.3 | 391.3 | 365.4 |
| 20 | 335.7 | 309 | 282.3 |
| 100 | 280.9 | 224.2 | 167.5 |
| 1000 | 108.4 | 82.2 | 56 |
| 10000 | 49.1 | 34.45 | 19.8 |
| 100000 | 18.3 | 13 | 7.7 |
| 1000000 | 10.1 | 6.95 | 3.8 |

Following is an example predicting the remaining life/consumed life for a voltage-clamping element due to a surge event. In this example, the peak temperature rise of the voltage-clamping element within 30 seconds after the event began was found to be 15 degrees, which results in a Trp of 10 (Trp is the difference between T_{Mp} and T_{M0}). According to the previous discussion concerning the timing of the peak temperature rise, it can be inferred that the event is a surge event and thus Table 2 is used for the analysis. More specifically, Equation 10 can be used to calculate the energy Qs of the surge event. Alternatively, Equation 2 can be used to first calculate Iₚₑₐₖ and then Equation 12 can be used to calculate the energy Qs. Based on the calculated Qs value, the waveform type, Table 2 and Equation 14, the life consumed by the event may be calculated.

For example, assuming the surge is an 8/20 μs surge wave, the energy Qs (based on Trp and Equation 10) for a specific voltage-clamping element is calculated as 186.64 Joules (Qs=a*Trp^{b}=186.64 J; or in the alternative, Ipeak=a*Trp^{b}=18.9 kA, and Qs=a*(Ipeak^{b})=186.64 J). This Qs (i.e., 186.64 J), assuming the optimistic column, is between 167.5 J (which corresponds to 100 pulses) and 308.5 J (which corresponds to 20 pulses; see table 2). Interpolating 184.64 J between 167.5 J (100 pulses) and 308.5 J (20 pulses) yields 71.26 pulses (optimistic; N=71.26), 41.65 (balanced; N=41.65) and 28.75 (pessimistic; N=28.75). Then the formula SLCP=1/N_s as shown in FIG. 3 can be used to calculate SLCP in different prediction modes.

$$SLCP = 1 / N\_s = 1 / 71.26 = 1.403 \% ( optimistic )$$

$$SLCP = 1 / N\_s = 1 / 41.65 = 2.401 \% ( Balanced )$$

$$SLCP = 1 / N\_s = 1 / 28.75 = 3.478 \% ( pessimistic )$$

The above process can be simplified to obtain Equation 14, in which Trp can be used to directly calculate the SLCP.

$$SLCP = a * {Trp}^{b} \qquad Equation 14$$

where
SLCP is the life consumed by the event (where a value of 1 corresponds to 100%, i.e., SLCP*100=percent life consumed),
Trp is the difference between T_{Mp} and T_{M0} (i.e., T_{Mp}−T_{M0}) in degrees C. (the peak temperature rise), and
a and b are coefficients of the voltage-clamping element (the coefficients (a and b) under optimistic, balanced and pessimistic modes are different as different data points are used, as discussed in further detail below).
   Accordingly, for a surge event and in the optimistic prediction model at such Q the voltage-clamping element can withstand such surge 20-100 times. Interpolating the calculated Q between 308.5 (15 pulses) and 123.3 (100 pulses) yields N=42.32, which means that the surge consumed (SLCP)=1/43.32=2.363% of surge life. In the balanced prediction model, at such Q the voltage-clamping element can withstand such surge 15-100 times, and interpolating the calculated Q between 292.7 J (15 pulses) and 104 J (100 pulses) yields N=34.16, which means that the surge consumed (SLCP)=1/34.16=2.927% of surge life. In the pessimistic prediction model, at such Q the voltage-clamping element can withstand such surge 15-100 times, and interpolating the calculated Q between 276.9 J (15 pulses) and 84.7 J (100 pulses) yields N=28.17, which means that the surge consumed (SLCP)=1/28.17=3.550% of surge life.

If an event occurs in which the peak temperature rise did not occur within 30 seconds of the event beginning, or the peak temperature rise does occur but its peak temperature rise is greater than 50 (the maximum temperature rise corresponding to Imax, the corresponding example model), values for Tr15, Tr30, and Tr60 are recorded. According to the previous discussion concerning FIG. 7, it can be inferred that the event is an overvoltage event and, thus, Table 3 is used for the analysis. More specifically, Equation 13 can be used to calculate the energy Q of the event based on the captured values for Tr15, Tr30, or Tr60, and based on the calculated Q value, and the bearable times N_o under optimistic, balanced, or pessimistic modes can be calculated based on the calculated Q value and Table 3, and finally calculate OLCP, as shown in Equation 15.

$$OLCP = 1 / N\_o \qquad Equation 15$$

Where N_o is the number of pulses and OLCP is the life consumed by the overvoltage event in percent. The process can be simplified to obtain Equation 16, which defines the life consumed by the overvoltage event (OLCP),

$$OLCP = a * {Trx}^{b} \qquad Equation 16$$

where
OLCP is the life consumed by the overvoltage event (where a value of 1 corresponds to 100%, i.e., OLCP*100=percent life consumed),
Trx is the temperature rise at x seconds after the event has initiated, and
a and b are coefficients of the voltage-clamping element.

For example, from the recorded values of Trx the energy Q can be calculated from Equation 13 at 206 Joules. In the optimistic overvoltage prediction model, at such Q the voltage clamping-element can withstand such surge 100-1000 times (see Table 3), and interpolating the calculated Q between 280.9.7 J (100 pulses) and 108.4 J (1000 pulses) yields N=132, which means that the surge consumed 1/132=0.758% of the lifetime. In the balanced prediction model, at such Q the voltage-clamping element can withstand the surge 100-1000 times, and interpolating the calculated Q between 224.2 J (100 pulses) and 82.2 J (1000 pulses) yields N=114, which means that the surge consumed 1/114=0.877% of the lifetime. In the pessimistic prediction model, at such Q the voltage-clamping element can withstand such surge 20-100 times, and interpolating the calculated Q between 282.3 J (20 pulses) and 167.5 (100 pulses) yields N=68, which means that the surge consumed 1/68=1.470% of the lifetime.

These two events are combined to determine the consumed life of the voltage-clamping element as shown in Equation 16,

$$TLCP = \sum OLCP + \sum SLCP \qquad Equation 16$$

where
TLCP is the total life consumed (where a value of 1 corresponds to 100%, i.e., TLCP*100=percent life consumed),
OCLP is the life consumed from the overvoltage event (where a value of 1 corresponds to 100%, i.e., OLCP*100=percent life consumed), and
SLCP is the life consumed from the surge current event (where a value of 1 corresponds to 100%, i.e., SLCP*100=percent life consumed).
   So in the present example for the optimistic model: TLCP=1.403%+0.758%=2.161% lifetime consumed, for the balanced mode: TLCP=2.401%+0.877%=3.278% lifetime consumed, and for the pessimistic mode: TLCP=3.478%+1.470%=4.948% lifetime consumed. When life consumption reaches 100%, it will be concluded that the voltage-clamping element is close to failure.

As is evident from the above discussion and in particular the equations, various coefficients are utilized to determine the parameters of the voltage-clamping element. Provided below is an example of how these coefficients may be derived for a particular voltage-clamping element.

Starting with Equations 2 and 3, a curve fitting method, regression analysis, interpolation, Fourier series, machine learning models, or other methods may be used to find coefficients a and b. For example, a series of tests can be performed to obtain surge current formula coefficients. In this regard, a single surge test from a minimum ( 1/10 In, where In is the nominal discharge current in amps) to a maximum (Imax) can be performed. In performing the test, a plurality of voltage-clamping elements are grouped into multiple groups (e.g., 8 groups), each group containing, for example, three voltage-clamping elements (one having a smaller V1 mA rating, one having V1 mA rating, and on having a larger V1 mA rating). A single surge test then is performed for each group of voltage-clamping elements, where the voltage-clamping elements are subjected to a sequence of surge currents at 1/10 In, ¼ In, ½ In, ¾ In, In, 1¼ In, 1½ In, 1¾ In, Imax (For example: 150TPMOVcSL: 2 kA, 4 kA, 10 kA, 16 kA, 20 kA, 30 kA, 50 kA). The voltage, current and temperature curves at each surge level are recorded with respect to time.

The data collected from the tests is sorted, where the average peak temperature rise (Trp) at each test current is used as the representative typical peak temperature rise (Trp) for that current. Table 4 below illustrates exemplary data that may be collected for each group.

TABLE 4

| | | |
|---|---|---|
| | 150TPMOVcSL example | Peak temperature rise |
| surge current | surge current sequence | measurement |
| sequence | Ipeak(kA) | Trp |

| | | | |
|---|---|---|---|
| 1/10 | In | 2 | 1.16 |
| ¼ | In | 5 | 3.02 |
| ½ | In | 10 | 6.91 |
| ¾ | In | 15 | 11.2 |

| | | |
|---|---|---|
| In | 20 | 16.1 |

| | | | |
|---|---|---|---|
| 1¼ | In | 25 | 21.9 |
| 1½ | In | 30 | 28.2 |
| 1¾ | In | 35 | 33.1 |

| | | |
|---|---|---|
| Imax | 50 | 48.6 |

A scatter chart for current and Trp then can be created, as illustrated in FIG. 15. The illustrated curve is defined by the equation y=ax^{b} (a and b being the coefficients of interest), and solving for a and b yields y=1.9x^{0.85}, where 1.9 is coefficient “a” and 0.85 is coefficient “b”. In the exemplary curve shown in FIG. 15, all data are actual sample data based on thermocouple measurements for a 150 amp voltage-clamping element. Actual data will vary based on product design and heat dissipation conditions.

To obtain the coefficients “c” and “d”, multiple continuous surge tests may be performed using equal current values for each of the groups of voltage-clamping elements described above (i.e., one having a smaller V1 mA, one having V1 mA, and on having a larger V1 mA). The surge test is repeated using a current sequence of ¼ In, ½ In and In, where In is the nominal discharge current in amps. Surge testing is repeated at 10 kA and the temperature of the voltage-clamping element is recorded, yielding the curve of FIG. 16. The first five samples of the data can be used to construct Table 5.

TABLE 5

| | | | | | | Difference | | |
|---|---|---|---|---|---|---|---|---|
| | | | | | | between | | |
| | | | | | | MOV and | | |
| | | | | | | ambient | | |
| | | | | | | temperature | | |
| | | | MOV | MOV | Peak | when surge | interval | Temperature |
| part | | Ambient | temperature | peak | temperature | discharge | between | drops |
| x1 | I | temperature | starting | temperature | rise | begins | two | during the |
| shot | peak(kA) | Ta | Tm0 | Tmp | Trp | Tdiff | shots | interval |
| 1 | 20.188 | 23.1 | 23.1 | 39.2 | 16.1 | 0 | 0 | −8.2 |
| 2 | 20.154 | 23.1 | 31 | 46.1 | 15.1 | 7.9 | 73 | −10.9 |
| 3 | 20.37 | 23.1 | 35.2 | 49.9 | 14.7 | 12.1 | 72 | −11.9 |
| 4 | 20.247 | 23.1 | 38 | 52.5 | 14.5 | 14.9 | 73 | −12.5 |
| 5 | 20.152 | 23.1 | 40 | 54.3 | 14.3 | 16.9 | 72 | −13 |

A surge may be inferred when the temperature of the voltage-clamping element is higher than the ambient temperature. The higher the voltage-clamping element temperature the faster the heat dissipation. Therefore, the voltage-clamping element loses more heat when it reaches its peak temperature, and thus temperature compensation is required for determining the coefficient c.

To make sure the equation Ipeak=a*T^{b} (Equation 3) is valid, Trp is compensated to T′=Tr+a*Tdiff. Table 6 below is derived based on Table 5, where the temperatures are in Kelvin.

TABLE 6

| | T | | |
|---|---|---|---|
| Tdiff | compensation | Trp | T′ = Trp + c*Tdiff |
| 0 | 0 | 16.1 | 16.1 |
| 7.9 | 1 | 15.1 | 16.1 |
| 12.1 | 1.5 | 14.7 | 16.1 |
| 14.9 | 1.6 | 14.5 | 16.1 |
| 16.9 | 1.8 | 14.3 | 16.1 |

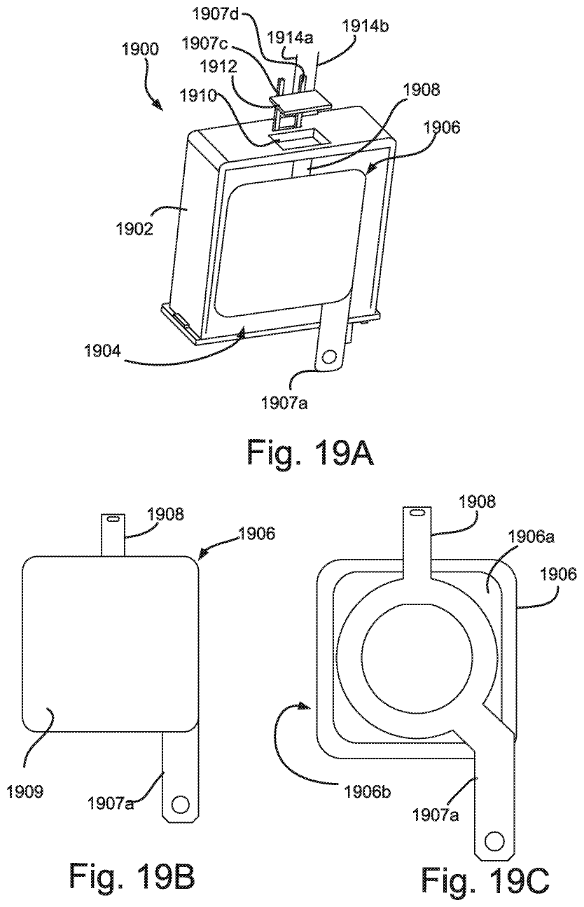

A scatter chart then is created based on Tdiff and Tcompensation. FIG. 19 illustrates an exemplary scatter chart, which can be approximated by a straight line (y=mx+b). Solving the equation yields y=0.1067x+0.0745 and, thus, the coefficient c is 0.1067. After 3 groups of tests are completed, three different values for c will be identified. Due to very small differences, the average c can be used as the temperature compensation coefficient.

Provided now is an example of how the coefficients utilized in the various equations may be obtained. It is noted that the coefficients will change depending on the characteristics of the specific type of voltage-clamping element and the specific formula for which the coefficient is being derived.

For Surge ( 8/20 μs), the following equations are relevant (see FIG. 3).

Ipeak=f(T′)≈f(Trp,Tdiff)

T′=f(Tdiff)=Trp+a*Tdiff+b≈Trp+a*Tdiff

Ipeak=a*T′\hat{ }b

For overvoltage, the following equation is relevant (see FIG. 3)

Iov=a*Trx+b

For example, in order to obtain the coefficient for the current due to overvoltage in the above formula, a sample voltage-clamping element is subjected to known overvoltage conditions and the resulting current through the voltage-clamping element and temperature change of the voltage-clamping element are recorded (e.g., a power supply is adjusted to simulate various overvoltage conditions, which in turn generates different constant currents). The collected data from an exemplary sample voltage-clamping element is shown in Table 7. This data then can be used to solve Iov=a*Trx+b.

TABLE 7

| current passing through MOV | Temperature change record |
|---|---|
| (mA) | (Tr15) |
| 20.5 | 2.4 |
| 30 | 3.9 |
| 47 | 7.9 |
| 58 | 8.9 |
| 67 | 11.3 |
| 78 | 10.6 |
| 85 | 11.6 |
| 90 | 12.6 |

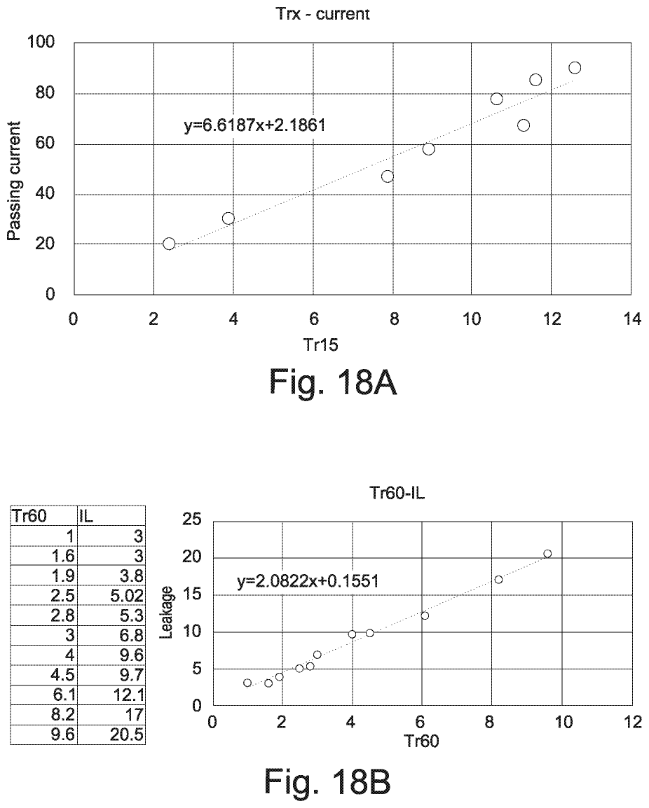

From the above data, linear aggregation can be used to obtain a formula and its coefficients as shown in FIG. 18A, to arrive at coefficient “a” of 6.6187 and coefficient “b” of 2.1861.

Iov=6.6187*Tr15+2.1861

For leakage current, the following formula is relevant (see FIG. 3).

I_{L}=a*Trx+b

The same process described above can be used to solve for the coefficients for leakage current. For example, samples with different degradation conditions are placed under maximum continuous operation voltage conditions, and the resulting leakage current and corresponding temperature changes are recorded, as shown in Table.

TABLE 8

| Leakage current passing through MOV | Temperature change record |
|---|---|
| (mA) | (Tr60) |
| 3 | 1 |
| 3 | 1.6 |
| 3.8 | 1.9 |
| 5.02 | 2.5 |
| 5.3 | 2.8 |
| 6.8 | 3 |
| 9.6 | 4 |
| 9.7 | 4.5 |
| 12.1 | 6.1 |
| 17 | 8.2 |
| 20.5 | 9.6 |

From the above data, curve fitting can be used to obtain the coefficients as shown in FIG. 18B, to arrive at coefficient “c” of 2.0822 and coefficient “d” of 0.1551

$${I}_{L} = 2.0822 * Tr 60 + 0.1551$$

Referring now to FIGS. 19A-19C, illustrated is an exemplary surge protection device (SPD) 1900 in accordance with another embodiment of the invention. The SPD 1900 is similar to the SPD 100 of FIGS. 1A-1B and thus only the differences are discussed here.

The SPD 1900 includes a housing 1902 that defines an interior space 1904, best seen in FIG. 18A in which a back wall of the housing 1902 is removed. A voltage-clamping element 1906 is attached to the housing 1902 and disposed at least partially within the interior space 1904. The voltage-clamping element 1906, which may be in the form of a metalized ceramic body (also referred to as a silver-plated disk) includes a first electrode 1906a and a second electrode 1906b (the second electrode 1906b disposed on a side opposite that of the first electrode 1906a) for electrically connecting the voltage-clamping element 1906 to a circuit to be protected. Attached (e.g., soldered) to the first and second electrodes 1906a, 1906b are first and second terminal electrodes 1907a, 1907b, respectively, the first and second terminal electrodes 1907a, 1907b extending out of the housing or are otherwise accessible external to the housing 1902. For example, the housing 1902 may include two slots formed in a bottom wall, where the first and second terminal electrodes 1907a, 1907b pass through the slots and extend out the bottom of the housing 1902. Status terminals 1907c, 1907d are accessible external to the housing 1902, the status terminals connected to a switch (not shown) that provides a status of the voltage-clamping element, e.g., operational or tripped.

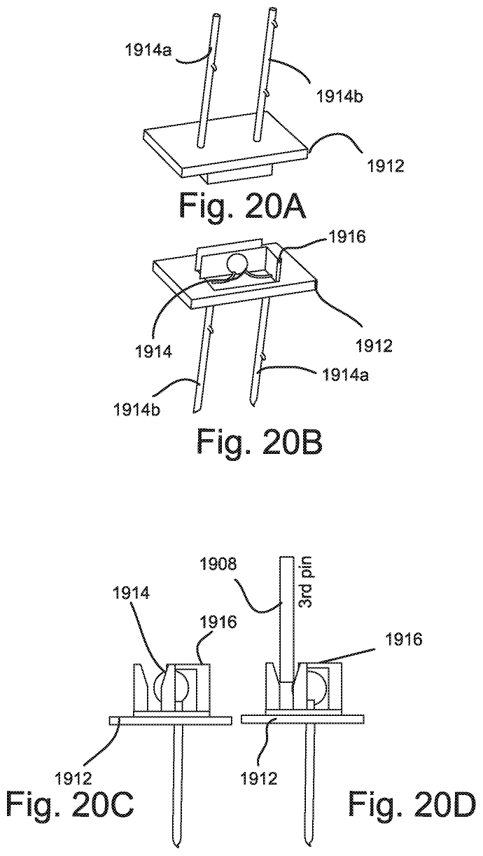

A thermal terminal 1908 is thermally connected to the voltage-clamping element 1906 and extends out of the housing 1902 or otherwise is accessible external to the housing 1902. For example, the housing 1902 may include a slot 1910 formed in a top wall of the housing 1902, where the thermal terminal 1908 passes through the slot 1910 and extends out the top of the housing 1902. Alternatively, and with additional reference to FIGS. 20A-20D, a cover 1912 may be placed over the slot 1910, where a bottom side of the cover 1912 connects to the thermal terminal 1908. A top or bottom side of the cover 1912 may include or otherwise enable connection to a temperature sensor, such as sensor 1914. In the illustrated embodiment, a support structure 1916 is disposed on a bottom side of the cover 1912. The support structure 1916 provides a mount for the temperature sensor 1914 and also a means for the thermal terminal 1908 to contact the temperature sensor, as best seen in FIG. 20D. First and second temperature terminals 1914a, 1914b are accessible external to the housing and enable connection of the temperature sensor 1914 to a monitoring circuit (not shown).

In the illustrated embodiment the thermal terminal 1908 is conductively connected to the first terminal electrode 1907a, as best seen in FIG. 19D. In other words, the thermal terminal 1908 may be an extension of the first terminal electrode 1907a (or optionally an extension of the second terminal electrode 1907b) and formed of the same material as the respective terminals electrode 1907a, 1907b, such a metal or like material. Alternatively, the thermal terminal 1908 may be directly connected to or integrally formed with the voltage-clamping element 1906, e.g., attached to or formed integral with a surface of the voltage-clamping element or attached to or formed integral with an electrode 1906a, 1906b of the voltage-clamping element, independent of the first and/or second terminals electrodes 1907a, 1907b. In some embodiments, the thermal terminal 1908 comprises a non-electrically conductive material such as AlN (Aluminum Nitride) or SiC (Silicon Carbide). For example, an electrically insulating material that is thermally conductive may be disposed on one or both of the electrodes 1906a, 1906b or one or both of the terminal electrodes 1907a, 1907b such that the thermal terminal 1908 is electrically isolated from the voltage-clamping element 1906, the first and second electrodes 1906a, 1906b, and the first and second terminal electrodes 1907a, 1907b, but thermally conductive so as to communicate thermal conditions of the voltage-clamping element 1906.

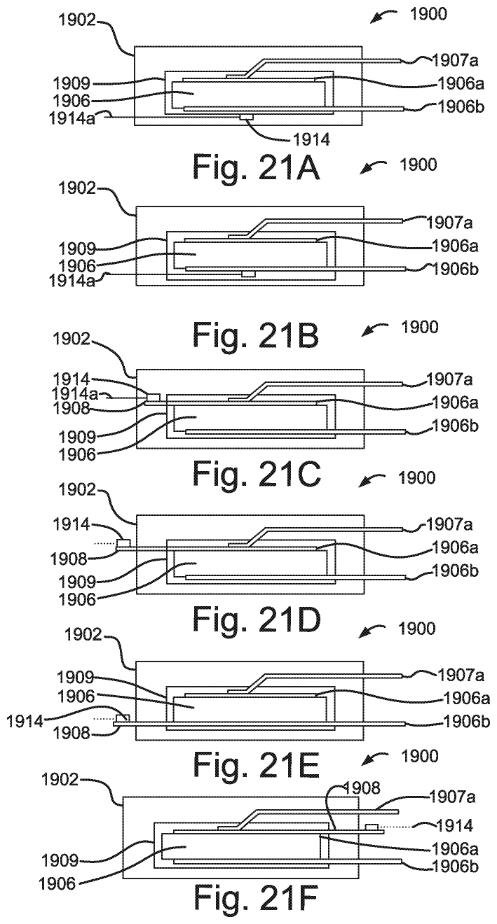

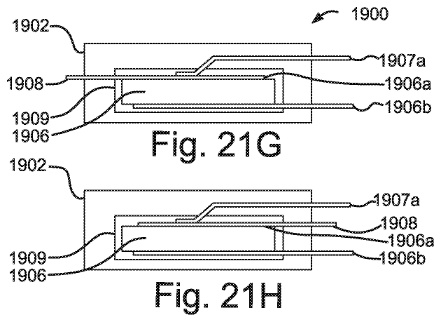

Referring now to FIGS. 21A-21H, illustrated are various configurations for an exemplary SPD 1900 in accordance with the invention. In each of the embodiments of FIGS. 21A-21H, the SPD 1900 includes a voltage-clamping element 1906 disposed in a housing 1902 and having a first electrode 1906a and a second electrode 1906b. A first terminal electrode 1907a is electrically connected to the first electrode 1906a and configured to disconnect from the electrode 1906a upon a temperature of the voltage-clamping element 1906 exceeding a prescribed temperature, thereby electrically disconnecting the voltage-clamping element 1906 from a circuit. The voltage-clamping element 1906, including the electrodes 1906a, 1906b, as well at least a portion of the terminal electrodes 1907a, 1907b, are optionally encapsulated within a resin material 1909 or the like. A temperature sensor 1914 is in thermal communication with the voltage-clamping element 1906 so as to provide temperature data corresponding to a temperature of the voltage-clamping element 1906.

In the embodiment of FIG. 21A, the temperature sensor 1914 is disposed outside the resin material 1909 and directly connected to the second electrode 1906b (which at least partially extends out of the resin material 1909). In the embodiment of FIG. 21B, the temperature sensor 1914 is disposed within the resin material 1909 and directly connected to electrode 1906b.

In the embodiment of FIG. 21C, the temperature sensor 1914 is connected to a thermal terminal 1908 that is in thermal communication with the electrode 1906a, the thermal terminal 1908 extending out of the resin material 1909. As can be seen in FIG. 21C, the temperature sensor 1914 is arranged within the SPD housing 1902.

The embodiments of FIGS. 21D, 21E and 21F are similar to the embodiment of FIG. 21C, except that the temperature sensor 1914 is disposed external to the housing 1902. Thus, in the embodiment of FIGS. 21D-21F the temperature sensor 1914 need not be part of the SPD 1900. In FIG. 21D, the thermal terminal 1908 is connected to electrode 1906a, while in FIG. 21E the thermal terminal 1908 is connected to electrode 1906b. In FIG. 21F the thermal terminal 1908 is connected to electrode 1906a and extends out from the housing 1902 in a different (opposite) direction from the thermal terminal illustrated in of FIGS. 21D and 21E.

In the embodiment of FIGS. 21G and 21H the SPD does not include a temperature sensor. In this embodiment, the thermal terminal 1908 extends out of the housing 1902 and a user can supply a temperature sensor, which monitors the thermal terminal 1908.

Modifications and alterations of the structures shown in the drawings will become apparent to those skilled in the art after reading the present specification. It is intended that all such modifications and all variations being included in so far as they come within the scope of the patent as claimed or the equivalence thereof.

Although the invention has been shown and described with respect to a certain embodiment or embodiments, equivalent alterations and modifications may occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein exemplary embodiment or embodiments of the invention. In addition, while a particular feature of the invention may have been described above with respect to only one or more of several embodiments, such feature may be combined with one or more other features of the other embodiments, as may be desired and advantageous for any given or particular application.

1. A surge protection device (SPD) couplable to a circuit, comprising:
a voltage-clamping element configured to limit a voltage; and
a processing device configured to receive temperature data corresponding to the voltage-clamping element, the processing device configured to determine, based on the temperature data, a temperature rise of the voltage-clamping element, and based on the temperature rise determine at least one of
an electrical parameter of the voltage-clamping element,
an electrical parameter of a circuit coupled to the SPD,
an amount of life of the voltage-clamping element consumed by the electrical event, or
a remaining life of the voltage-clamping element after the electrical event.

2. The SPD according to claim 1, further comprising a first temperature sensor configured to measure a temperature of the voltage-clamping element, the first temperature sensor communicatively coupled to the processing device to provide the temperature data to the processing device.

3. The SPD according to claim 2, further comprising:
a housing including an interior space, wherein the voltage-clamping element is disposed at least partially within the interior space; and
a thermal terminal thermally connected to the voltage-clamping element, wherein the first temperature sensor is disposed external to the housing and thermally connected to the thermal terminal.

4. The SPD according to claim 1, wherein said determination is based solely on the temperature rise of the voltage-clamping element.

5. The SPD according to claim 1, further comprising a second temperature sensor communicatively coupled to the processing device and configured to measure a temperature of ambient air about the voltage-clamping element, wherein the processing device is further configured to base said determination on the ambient air temperature about the voltage-clamping element.

6. The SPD according to claim 1, wherein the processing device includes a communication module configured to communicate with other equipment.

7. The SPD according to claim 1, further comprising:
a first terminal and a second terminal for connecting the surge protection device to a circuit to be protected; and
a thermal protection element;
wherein the voltage-clamping element and the thermal protection element are electrically connected in series between the first and second terminals, and the thermal protection element configured to disconnect the voltage-clamping element from at least one of the first or second terminals upon detecting an overload condition.

8. The SPD according to claim 1, wherein the processing device is configured to determine a surge or an over voltage applied to the voltage-clamping element as a function of the temperature rise.

9. The SPD according to claim 1, wherein the processing device is configured to determine a current through the voltage-clamping element as a function of the temperature rise.

10. The SPD according to claim 1, wherein the processing device is configured to determine a leakage current of the voltage-clamping element as a function of the temperature rise.

11. The SPD according to claim 1, wherein the processing device is configured to determine an amount of energy absorbed by the voltage-clamping element as a function of the temperature rise.

12. A method for detecting an electrical parameter of a voltage-clamping element, comprising:
measuring a temperature of the voltage-clamping element;
based on the measured temperature, determining a temperature rise of the voltage-clamping element; and
calculating the electrical parameter of the voltage-clamping element based on the temperature rise.

13. The method according to claim 12, wherein calculating the electrical parameter is based solely on the temperature rise of the voltage-clamping element.

14. The method according to claim 12, further comprising measuring an ambient temperature about the voltage-clamping element, and wherein calculating the electrical parameter is based on the temperature rise of the voltage-clamping element and the ambient air temperature.

15. The method according to claim 12, wherein the electrical parameter is one of a surge or over voltage applied to the voltage-clamping element, a current applied to the voltage-clamping element, a leakage current of the voltage-clamping element, or an energy absorbed by the voltage-clamping element.

16. A surge protection device (SPD), comprising:
a housing including an interior space; and
a voltage-clamping element disposed at least partially within the interior space, the voltage clamping element comprising a first electrode and a second electrode for electrically connecting the voltage-clamping element to a circuit to be protected, and a thermal terminal thermally connected to the voltage-clamping element, the first and second electrodes extending out of the housing.

17. The SPD according to claim 16, wherein the thermal terminal is connected to one of the first electrode or the second electrode.

18. The SPD according to claim 16, wherein the thermal terminal and one of the first or second electrodes are conductively connected to each other.

19. The SPD according to claim 16, wherein the thermal terminal is connected to a surface of the voltage-clamping element.

20. The SPD according to claim 19, wherein the thermal terminal comprises a non-electrically conductive material.

21. The SPD according to claim 16, further comprising a temperature sensor disposed external to the housing, the temperature sensor thermally coupled to the thermal terminal.

22. The SPD according to claim 21, further comprising a status indicator configured to provide a status of the voltage-clamping element.

23. The SPD according to claim 22, wherein the temperature sensor and the surge protection device are electrically coupled to terminals accessible external to the housing, wherein at least one of:
the terminals comprise a first terminal and a second terminal, and the temperature sensor and the status indicator are electrically connected to the first terminal and the second terminal in a parallel or series configuration;
the terminals comprise a first terminal, a second terminal and a third terminal, and the temperature sensor and the status indicator are each electrically connected to the first terminal, the status indicator is further electrically connected to the second terminal, and the temperature sensor is further electrically connected to the third terminal; or
the terminals comprise a first terminal, a second terminal, a third terminal and a fourth terminal, and the temperature sensor is electrically connected to the first terminal and the second terminal, and the status indicator is electrically connected to the third terminal and the fourth terminal.

24. A method for estimating an amount of life of a voltage-clamping element consumed due to an electrical event, the method comprising:
obtaining a temperature rise of the voltage-clamping element due to the electrical event;
based on the temperature rise of the voltage clamping element, determining a pulse energy absorbed by the voltage-clamping element due to the electrical event; and
obtaining energy absorption characteristics of the voltage-clamping element;
determining the amount of life of the voltage-clamping element consumed due to the electrical event based on the pulse energy absorbed by the voltage-clamping element and the energy absorption characteristics of the voltage-clamping element.

25. The method according to claim 24, wherein obtaining the energy absorption characteristics of the voltage-clamping element comprises converting electrical specifications of the voltage-clamping element to an energy absorption curve representing a maximum amount of energy the voltage-clamping element can absorb.

26. The method according to claim 24, wherein the energy absorption characteristics include a maximum energy absorption of the voltage-clamping element, further comprising:
determining a cumulative energy absorbed by the voltage-clamping element over a prescribed time period; and
determining a remaining life of the voltage clamping element based a difference between the maximum energy absorption and the cumulative energy absorbed by the voltage-clamping element.

27. The method according to claim 24, further comprising determining a type of the electrical event, wherein determining the amount of life consumed is based on a type of electrical event.

28. The method according to claim 27, wherein the type of event is one of a surge event or an over voltage event.

29. An electrical device couplable to a circuit, comprising:
a circuit protection element; and
a processing device configured to receive temperature data corresponding to the circuit protection element, the processing device configured to determine, based on the temperature data, a temperature rise of the circuit protection element, and based on the temperature rise determine at least one of
an electrical parameter of the circuit protection element,
an electrical parameter of a circuit coupled to the circuit protection element,
an amount of life of the circuit protection element consumed by the electrical event, or
a remaining life of the circuit protection element after the electrical event.

30. The electrical device according to claim 29, wherein the circuit protection element comprises a fuse.
